(19) United States
(12) Patent Application Publication
(10) Pub. No.: US 2025/0355428 A1
(43) Pub. Date: Nov. 20, 2025

(54) PROCESSING METHOD, GENERATING DEVICE, PROCESSING SYSTEM, PROGRAM, AND STORAGE MEDIUM

(71) Applicants: KABUSHIKI KAISHA TOSHIBA, Tokyo (JP); TOSHIBA DIGITAL SOLUTIONS CORPORATION, Kawasaki-shi (JP)

(72) Inventors: Mio OHMURA, Yokohama (JP); Satoru ASAGIRI, Yokohama (JP); Hideki OGAWA, Hino (JP); Yoshiyuki OOISHI, Yokohama (JP)

(73) Assignees: KABUSHIKI KAISHA TOSHIBA, Tokyo (JP); TOSHIBA DIGITAL SOLUTIONS CORPORATION, Kawasaki-shi (JP)

(21) Appl. No.: 18/868,397

(22) PCT Filed: May 24, 2023
(86) PCT No.: PCT/JP2023/019319

§ 371 Date: Nov. 22, 2024

(30) Foreign Application Priority Data
May 30, 2022 (JP) 2022-087804

(51) Int. Cl. G05B 19/418

(52) U.S. Cl. CPC G05B 19/41875; G05B 19/4184

(57) ABSTRACT

There are provided a processing method, a generating device, a processing system, a program, and a storage medium capable of generating measures that are more effective in remedying defects. A processing method according to an embodiment causes a computer to refer to an individual model indicating a measure against a cause of a defect mode in a product. The processing method further causes the computer to generate consolidated models for a plurality of the defect modes respectively. Each consolidated model of the consolidated models is generated by rearranging and connecting a plurality of the individual models in accordance with a plurality of weights respectively set for a plurality of the causes.

### TECHNICAL FIELD

Embodiments of the invention relate to a processing method, a generating device, a processing system, a program, and a storage medium.

### BACKGROUND ART

In general, upon the occurrence of a defect, measures against the defect are implemented. Preferably, the measures are more effective in remedying the defect.

### PRIOR ART DOCUMENTS

### Patent Literature

[Patent Literature 1] JP2020-87110A

### SUMMARY OF INVENTION

### Problem to be Solved by the Invention

A problem to be solved by the invention is to provide a processing method, a generating device, a processing system, a program, and a storage medium capable of generating measures that are more effective in remedying defects.

### Means for Solving the Problem

A processing method according to an embodiment causes a computer to refer to an individual model indicating a measure against a cause of a defect mode in a product. The processing method further causes the computer to generate consolidated models for a plurality of the defect modes respectively. Each consolidated model of the consolidated models is generated by rearranging and connecting a plurality of the individual models in accordance with a plurality of weights respectively set for a plurality of the causes.

### BRIEF DESCRIPTION OF DRAWINGS

FIG. 1 is a flowchart showing a processing method according to an embodiment.

FIG. 2 shows example data saved in a first database.

FIG. 3 shows example data saved in a second database.

FIG. 4 shows an example of a generated consolidated model.

FIG. 5 shows example data stored in a third database.

FIG. 6 shows example data stored in the third database.

FIG. 7 shows example data stored in the third database.

FIG. 8 shows example data stored in the third database.

FIGS. 9A to 9C show example data stored in the third database.

FIG. 10 shows example data stored in the third database.

FIG. 11 shows example data stored in the third database.

FIG. 12 shows example data stored in the third database.

FIG. 13 shows example data stored in the third database.

FIG. 14 shows example data stored in the third database.

FIG. 15 shows example data stored in the third database.

FIG. 16 shows example data stored in the third database.

FIGS. 17A to 17E show example data stored in the third database.

FIGS. 18A to 18E show example data stored in the third database.

FIG. 19 shows example data usable in the processing method according to the embodiment.

FIG. 20 shows example data usable in the processing method according to the embodiment.

FIG. 21 shows example data usable in the processing method according to the embodiment.

FIG. 22 shows example data usable in the processing method according to the embodiment.

FIG. 23 is a schematic diagram illustrating a consolidated model.

FIG. 24 is a schematic diagram illustrating a consolidated model.

FIG. 25 is a schematic diagram showing a processing system according to the embodiment.

FIG. 26 is a schematic diagram showing a manufacturing line for a mounted board.

FIG. 27 is a schematic diagram showing a processing system according to an example.

FIG. 28 shows example output by a generating device according to the embodiment.

FIG. 29 shows example output by the generating device according to the embodiment.

FIG. 30 shows example output by the generating device according to the embodiment.

FIG. 31 shows example output by the generating device according to the embodiment.

FIG. 32 shows example output by the generating device according to the embodiment.

FIG. 33 shows example output by the generating device according to the embodiment.

FIG. 34 shows example output by the generating device according to the embodiment.

FIG. 35 is a schematic diagram showing a hardware configuration.

### DESCRIPTION OF EMBODIMENTS

Hereinafter, embodiments of the invention will be described with reference to the drawings. In the specification and drawings, components similar to those already described are marked with like reference numerals, and a detailed description is omitted as appropriate.

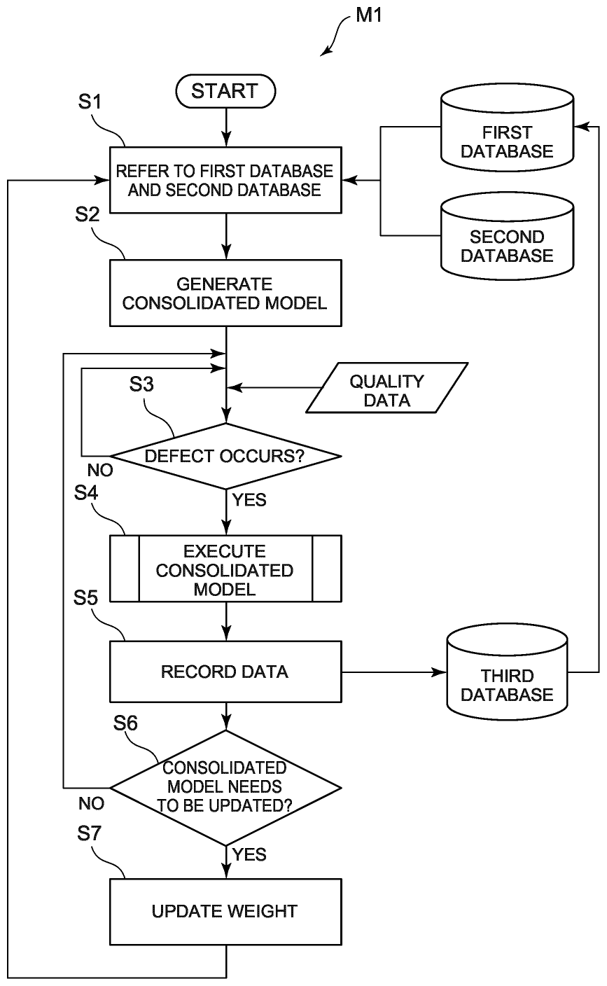

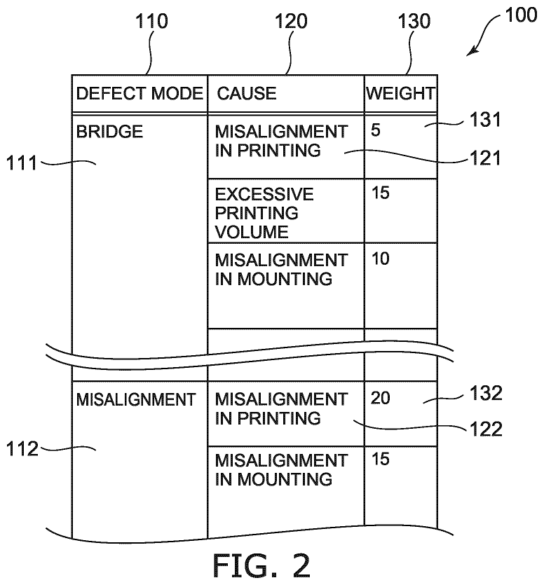

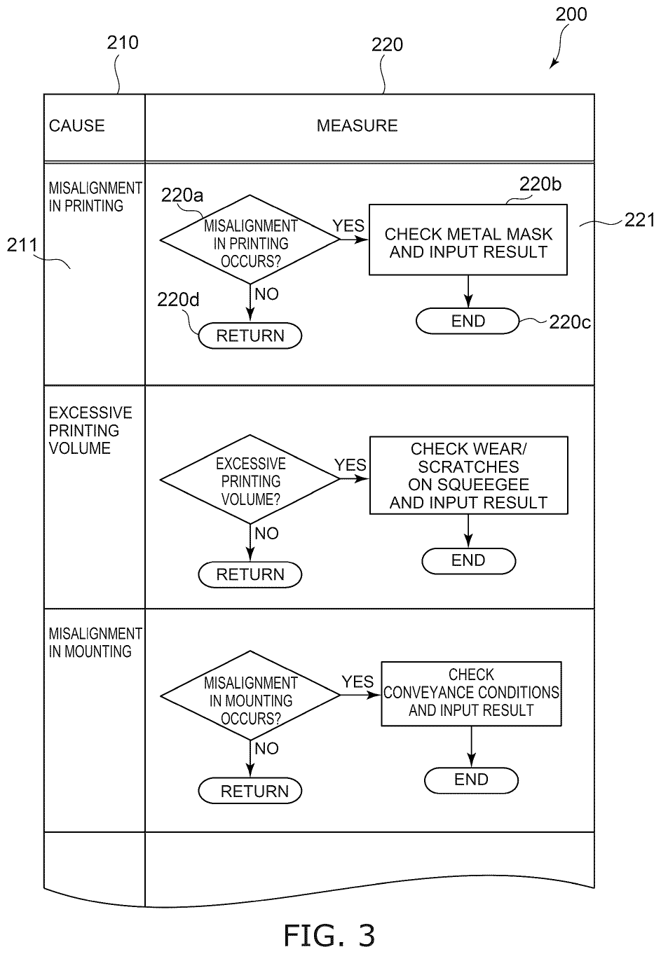

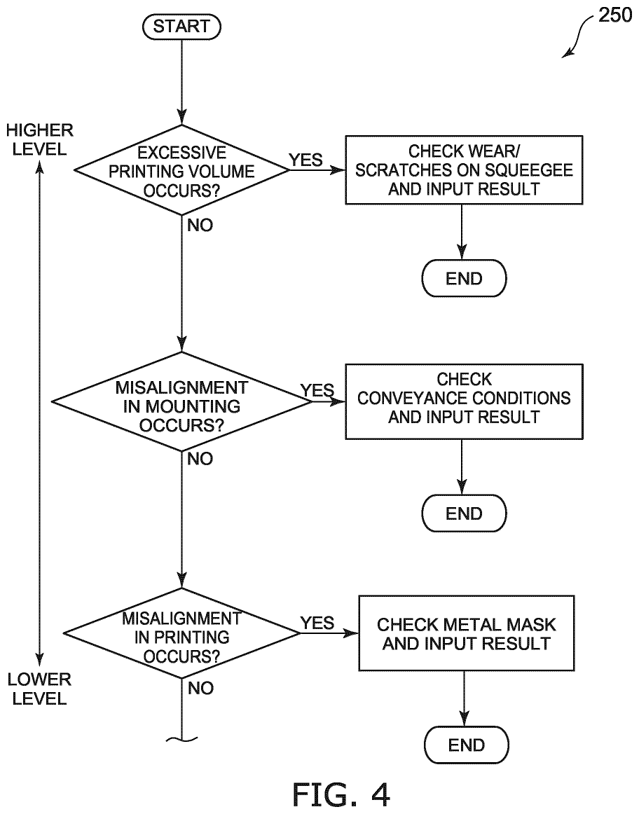

FIG. 1 is a flowchart showing a processing method according to an embodiment. FIG. 2 shows example data saved in a first database. FIG. 3 shows example data saved in a second database. FIG. 4 shows an example of a generated consolidated model.

The embodiment relates to a processing method for generating a model for improving a product. As shown in FIG. 1, a processing method M1 includes steps S1 to S7.

First, the first database and the second database are referred to (step S1). The first database stores a defect mode that can occur in the product, a cause of the defect mode, and the weight of the cause. The second database stores a cause and an individual model indicating a measure against the cause.

As shown in FIG. 2, a first database 100 stores a plurality of defect modes 110, and one or more causes 120 are associated with each of the defect modes 110. For each of the causes 120, a weight 130 is set. The defect mode 110 is a mode classification indicating a defect (for example, a trouble, a malfunction, a failure, or a fault) that can occur in the product. The cause 120 indicates a cause of the defect mode 110. One or more causes 120 are associated with one defect mode 110. The weight 130 indicates the importance level of the cause 120. In this example, a greater weight indicates that the importance level of the cause 120 is higher. For example, as the weight 130 is greater, it indicates that the possibility of the corresponding cause 120 being a cause of the defect mode 110 is higher. Alternatively, as the weight 130 is greater, it indicates that the removal of the corresponding cause 120 contributes to remedying of the defect mode 110 to a larger degree.

A common cause 120 can be set for different defect modes 110. In the example in FIG. 2, the same causes 121 and 122 of “misalignment in printing” are associated with a defect mode 111 of “bridge” and a defect mode 112 of “misalignment”. Even in this case, a weight 131 of the cause 121 and a weight 132 of the cause 122 can be different from each other. This is because the 10 influence of each cause 120 on the defect modes 110 can differ among the defect modes 110. The same applies to “misalignment in mounting”.

As shown in FIG. 3, a second database 200 stores a plurality of causes 210 and a plurality of individual models 220. The cause 210 is associated with the cause 120 and indicates a cause of the defect mode 110. The individual model 220 indicates a measure against the cause 210. One individual model 220 is associated with one cause 210. The individual 20 model 220 may be executed by a person. At least part of the individual model 220 may be described in a programming language and may be automatically executed by a computer.

A plurality of causes 120 having the same description in the first database 100 are associated with one cause 210. For example, both the causes 121 and 122 of “misalignment in printing” in FIG. 2 are associated with a cause 211. An individual model 221 associated with the cause 211 is a measure against the causes 121 and 122.

Each individual model 220 includes a determination 220a, processing 220b, an end terminal 220c, and a return terminal 220d. The determination 220a is a step of determination as to whether the cause 210 is occurring. In the example shown in FIG. 3, in any of the individual models 220, the first step is the step of determination. Before the determination 220a, one or more other steps selected from among, for example, processing, preparation, input/output, and display may be performed. The first step can be a step that is performed first in a consolidated model, which is a main routine. If it is determined in the determination 220a that the cause 211 is occurring, the step of the processing 220b is performed. The end terminal 220c indicates the end of the individual model 220 and the consolidated model. After the processing 220b is performed, the individual model 220 and the consolidated model end. If it is not determined in the determination 220a that the cause 211 is occurring, the flow proceeds to the return terminal 220d, and the first step in another individual model 220 is performed. When the return terminal 220d is not connected to the other individual models 220, the consolidated model ends.

Next, for each defect mode in the first database, individual models stored in the second database are rearranged and connected to each other in accordance with the weights set for the respective causes (step S2). Accordingly, a consolidated model is generated.

In the example shown in FIG. 2, for the defect mode 111 of “bridge”, the weight of “excessive printing volume” is greater than the weight of “misalignment in mounting”. The weight of “misalignment in mounting” is greater than the weight of “misalignment in printing”. In accordance with the weights, the individual model for “misalignment in mounting” is arranged at a higher level than the individual model for “misalignment in printing” as shown in FIG. 4. The individual model for “excessive printing volume” is arranged at a higher level than the individual model for “misalignment in mounting”. Among the individual models, the return terminal and the first step are connected to thereby generate a consolidated model 250 for remedying the defect mode.

Next, a determination as to whether a defect occurs in the product is performed (step S3). For example, the product is inspected in the middle of production or in an inspection process after production. Based on the result of inspection, quality data of the product is input into a predetermined database or a terminal device. When a defect is identified in the inspection, information about the defect is included in the quality data.

When the information indicating the occurrence of the defect is included in the quality data, a consolidated model generated for a defect mode into which the defect is classified is executed (step S4). For example, when the quality data includes information indicating the occurrence of “bridge”, a consolidated model corresponding to “bridge” is extracted from a plurality of generated consolidated models. The extracted consolidated model shown in FIG. 4 is executed.

The consolidated model may be executed by a person. At least part of the consolidated model may be described in a programming language and may be automatically executed by a computer. Upon the execution of the consolidated model, check data regarding causes is collected. For example, when the consolidated model shown in FIG. 4 is executed, first, a computer outputs, to an output device, an instruction to check to see if the printing volume of solder paste is excessive. The computer accepts check data indicating the result of the check by a person. The check data may be automatically collected by an inspection device. For example, when check data indicating that the printing volume is excessive is input, the computer outputs an instruction to check wear or scratches on the squeegee. The computer outputs an instruction to input the check data, and accepts an input of the check data.

Processing in one individual model may be described in one program file or may be divided and described in a plurality of program files. Similarly, processing in the consolidated model may be described in one program file or may be divided and described in a plurality of program files. The program files may be executed by different entities.

The check data obtained as a result of execution of the consolidated model is recorded in a third database (step S5). The third database stores, for the target product, for example, the number of occurrences of each cause and the configuration of the production line of the product.

The weights of causes saved in the first database are set on the basis of data stored in the third database. When the data stored in the third database is updated, there is a possibility that a weight in the first database changes. When a weight changes, there is a possibility that the sequence of the individual models included in the consolidated model changes. Therefore, when a weight is changed, a determination as to whether the consolidated model needs to be updated is performed (step S6).

If the consolidated model needs to be updated, the weight is updated (step S7). Thereafter, step S1 is performed again. That is, a new consolidated model is generated in accordance with the updated weight.

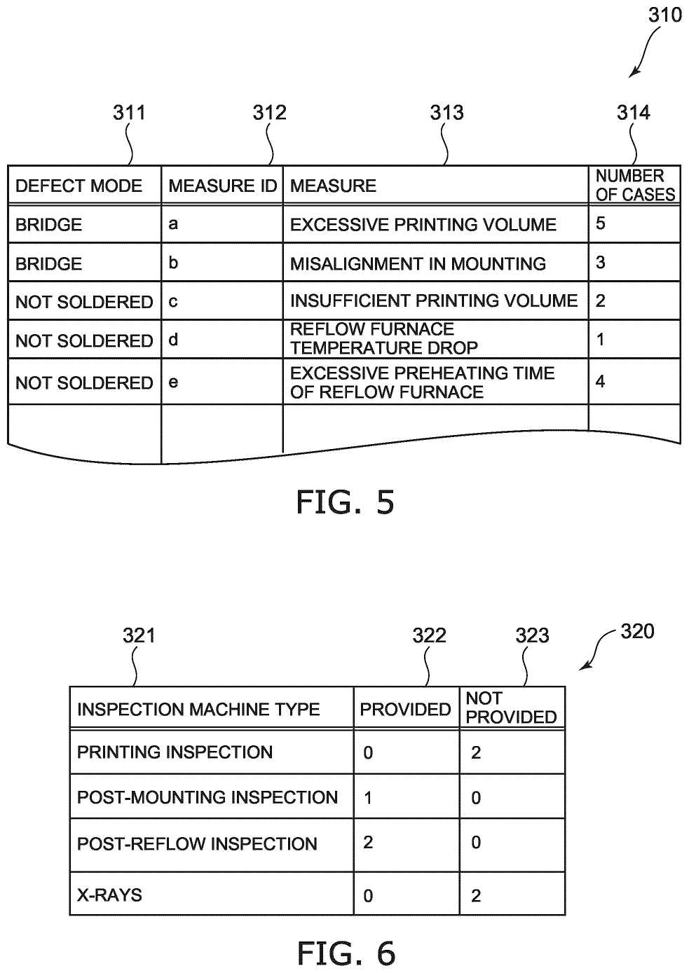

FIG. 5 to FIG. 18E show example data stored in the third database.

The weights in the first database vary in accordance with scores based on the data stored in the third database. A table 310 shown in FIG. 5 includes a defect mode 311, a measure ID 312, a measure 313, and a number of cases 314. The defect mode 311 corresponds to the defect mode 110 in the first database. The measure 313 indicates an individual model for a cause. The measure ID 312 is indicated by letters for identifying respective measures 313. When each measure 313 can be identified with a combination of the name of the defect mode 311 and the name of the measure 313, the measure ID 312 may be omitted. The number of cases 314 indicates the number of cases where the occurring defect mode is resolved by the measure 313. In other words, the number of cases 314 indicates the number of occurrences of a cause corresponding to the measure 313. The more the defect mode 311 is resolved by the measure 313, the more it indicates that the measure 313 is effective. For example, as the number of cases 314 is larger, a higher score is set for the measure 313, and a greater weight is set for the cause 120 associated with the measure 313. The number of cases 314 may be used as the score.

FIG. 6 shows a table 320 indicating scores according to the presence and absence of an inspection machine. The table 320 includes an inspection machine type 321, a score 322, and a score 323. The score 322 indicates a score when the inspection machine is provided. The score 323 indicates a score when the inspection machine is not provided. In a process in which an inspection machine is provided, a defect is more likely to be detected. When a defect is detected, an influence on the subsequent process can be reduced. Therefore, as shown in FIG. 6, the score may change in accordance with the presence or absence of the inspection machine in each process. Specifically, in a case where an inspection machine is provided, a lower score is set than in a case where the inspection machine is not provided.

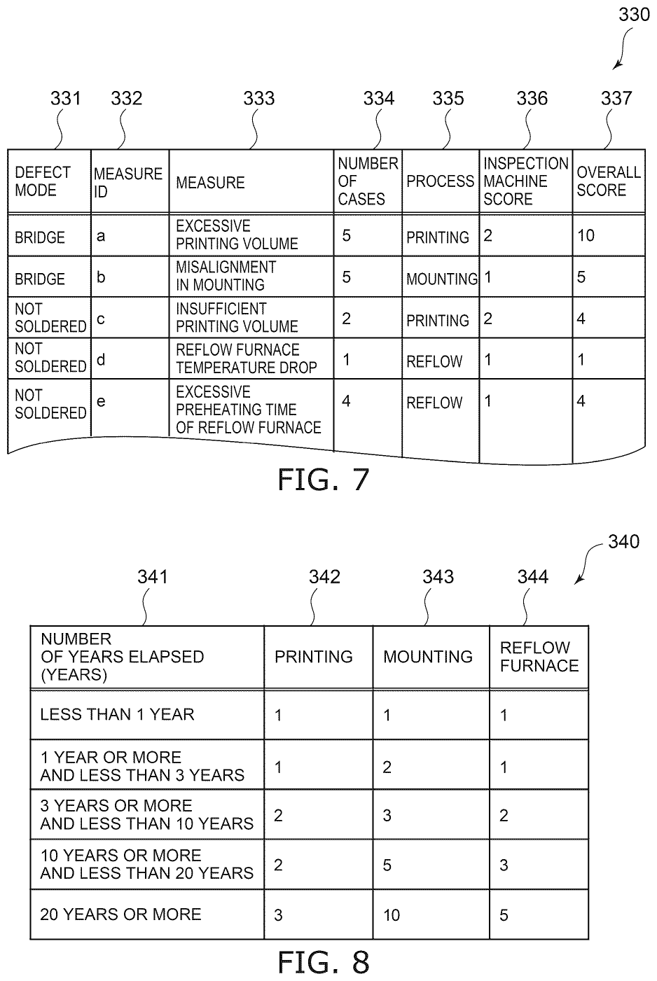

Based on the data shown in FIG. 5 and FIG. 6, a table 330 shown in FIG. 7 may be generated. The table 330 includes a defect mode 331, a measure ID 332, a measure 333, a number of cases 334, a process 335, an inspection machine score 336, and an overall score 337. The defect mode 331, the measure ID 332, the measure 333, and the number of cases 334 respectively correspond to the defect mode 311, the measure ID 312, the measure 313, and the number of cases 314 in the table 310. The process 335 indicates a process in which the defect mode 331 can occur. The inspection machine score 336 is a score according to whether an inspection machine is provided in the process, and is based on the table 320 shown in FIG. 6. The overall score 337 is an overall score based on the number of cases 334 and the inspection machine score 336. In this example, the overall score 337 is calculated as the product of the number of cases 334 and the inspection machine score 336.

The correspondence between the defect mode and the process and the correspondence between the process and the inspection machine may be stored in the tables 310 and 320 shown in FIG. 5 and FIG. 6 or may be stored in a table different from these tables.

The number of cases 334 may be adjusted in accordance with the time of the occurrence of the corresponding cause. In an example, when a score based on the number of cases 334 is denoted by Sc, the number of all past occurrences is denoted by nₐₗₗ, the number of past occurrences in the last m months is denoted by nₘ, and a certain factor is denoted by α (0≤α≤1), the score Sc is expressed by the following expression.

$$Sc = α \times {n}_{m} / {n}_{all} + ( 1 - α ) \times ( {n}_{all} - {n}_{m} ) / {n}_{all}$$

For example, when the influence of the last m months on weights is made larger, α is set to 0.5<α≤1. When the influence of the last m months on weights is made smaller, α is set to 0≤α<0.5. In a case of α=0.5, there is no weight according to the period. The overall score 337 is set on the basis of the score Sc based on the adjusted number of cases 334 and the inspection machine score 336.

As the time, the season may be taken into consideration. When a score based on the number of cases 334 is denoted by Sc, the number of all past occurrences is denoted by nₐₗₗ, the number of occurrences in spring (from March to May) is denoted by n_{Spring}, the number of cases in summer (from June to August) is denoted by n_{Summer}, the number of occurrences in autumn (from September to November) is denoted by n_{Autumn}, the number of occurrences in winter (from December to February) is denoted by n_{Winter}, and certain factors are denoted by α1 to α4, the score Sc is expressed by the following expression. The factors α1 to α4 are each greater than or equal to 0 and less than or equal to 1, and are set so that the sum of α₁ to α₄ is equal to 1.

$$S c = ( {α}_{1} \times {n}_{Spring} + {α}_{2} \times {n}_{Summer} + {α}_{3} \times {n}_{Autumn} + {α}_{4} \times {n}_{Winter} ) / 4 \times {n}_{all}$$

For example, when the occurrence in step S3 is in winter and when the influence of the number of occurrences in winter on weights is made larger than that in the other seasons, the factor α₄ is made larger than the factors α1 to α3.

A table 340 shown in FIG. 8 includes a number of years elapsed 341 and scores 342 to 344. The number of years elapsed 341 indicates the number of years elapsed since the manufacture of manufacturing equipment provided in the production line. In general, as the manufacturing equipment is older, a defect is more likely to occur in the process. As the possibility of the occurrence of a defect is higher, the scores are made higher. The scores 342 to 344 indicate scores for respective specific processes. The correlation between manufacturing equipment and a defect differs from process to process. Therefore, a score is set for each combination of a process and the number of years elapsed.

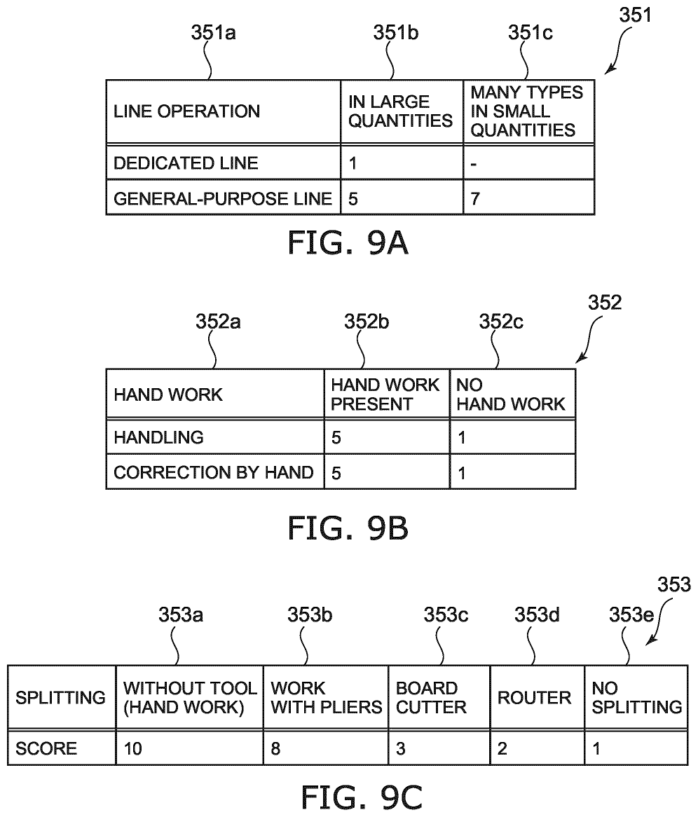

A table 351 shown in FIG. 9A includes a line operation 351a and scores 351b and 351c. The line operation 351a indicates information regarding an operation form in each process or each production line. The scores 351b and 351c indicate scores according to production forms in each line operation form. In general, in a dedicated line for producing only a specific product, the number of products to be produced is one, and no change due to changeover is made in manufacturing conditions. Therefore, the state changes less often, and a defect is less likely to occur once a stable state is created. Therefore, the scores are made lower. Meanwhile, in a line in which a plurality of types of products are produced in large quantities or in a line in which many types of products are produced in small quantities, a defect is more likely to occur, and the proportion of defects to the entirety increases. An influence on the production site is large, and therefore, the scores are made higher.

A table 352 shown in FIG. 9B includes a work form 352a and scores 352b and 352c for certain work. In general, as human work increases, the possibility of the occurrence of a defect increases. Therefore, in a case where there is human work, the scores are made higher than in a case where there is no human work.

A table 353 shown in FIG. 9C includes, for board splitting work, scores 353a to 353e for respective work forms. As shown in FIGS. 9B and 9C, each score may be set in accordance with the relationship between a specific operation form and the possibility of the occurrence of a defect or the relationship between the operation form and an influence of the defect. When scores are set on the basis of the configuration of the production line as shown in FIG. 8 and FIGS. 9A to 9C, weights can be more appropriately set.

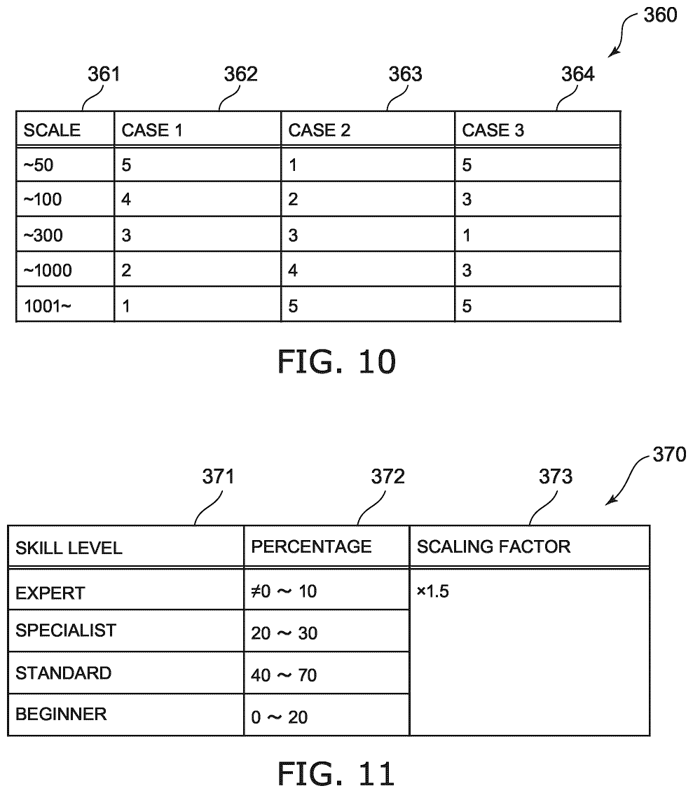

A table 360 shown in FIG. 10 includes a scale 361 and scores 362 to 364. The scale 361 indicates the scale of staff in the production site of the product. The scores 362 to 364 indicate scores in respective cases according to the scale. In case 1, the score is made higher as the scale of staff is smaller. For example, as the scale is smaller, know-how tends to be less accumulated. When the number of individual models to be executed is increased, know-how can be augmented. When this idea is assumed, scores are set as in case 1. In case 2, the score is made lower as the scale of staff is smaller. In a small-scale business entity, manpower for executing individual models is insufficient, and execution of only minimum necessary individual models may be required. When this idea is assumed, scores are set as in case 2. Taking into consideration both cases 1 and 2, scores may be set as in case 3. Whether to use scores in which case is determined before the processing method M1 is performed.

A table 370 shown in FIG. 11 includes a skill level 371, a percentage 372, and a scaling factor 373. For the data shown in FIG. 10, the percentage of each skill level as shown in FIG. 11 may be further taken into consideration. The skill level 371 indicates the skill levels (degrees of proficiency) of workers at the production site. The percentage 372 indicates the percentage of the number of workers at each skill level to the number of all workers. The scaling factor 373 indicates a scaling factor by which the scores in the table 360 are multiplied. In a production site in which there are no skilled people or there are excessively many beginners, the possibility of the occurrence of a defect is high. When the percentage of workers at any of the skill levels is outside the range specified as the percentage 372, the scores in the table 360 are multiplied by the set scaling factor 373.

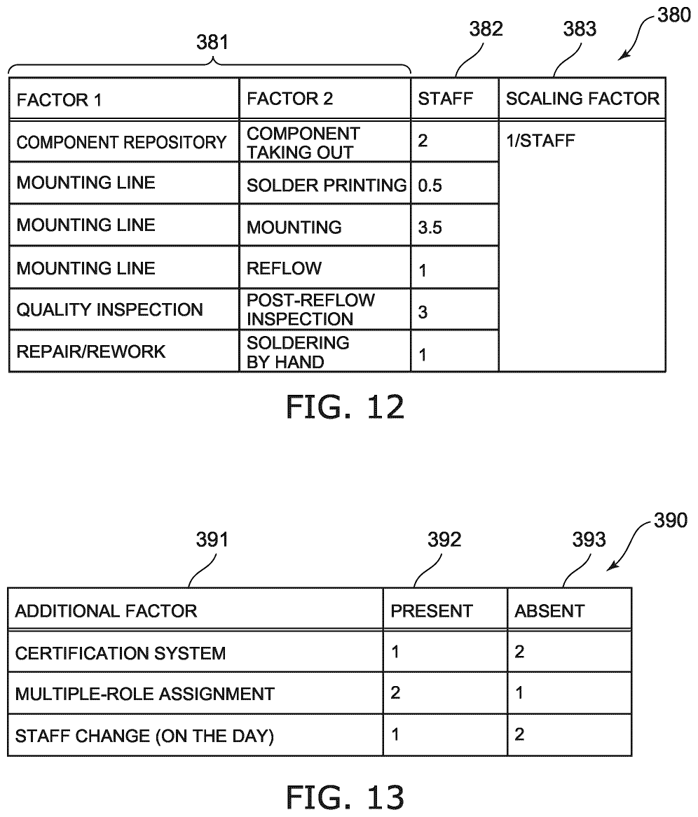

A table 380 shown in FIG. 12 includes a factor 381, staff 382, and a scaling factor 383. For the data shown in FIG. 7 or FIG. 10, the factors for respective processes as shown in FIG. 12 may be further taken into consideration. The factor 381 indicates, for example, facilities and processing in processes. The staff 382 indicates the number of staff members involved in each factor 381. The scaling factor 383 indicates a scaling factor by which scores related to the processes are multiplied. In general, as the number of staff members is larger, the possibility that manpower for executing individual models is sufficient is higher. Therefore, as the number of staff members is larger, the scaling factor is made lower. When remedying of a defect takes precedence, a value proportional to the number of staff members may be set as the scaling factor 383.

A table 390 shown in FIG. 13 includes an additional factor 391, a score 392, and a score 393. The additional factor 391 indicates an additional factor related to a worker. In this example, as the additional factor 391, “certification system” related to the technique and knowledge of a worker, multiple-role assignment to a worker in a plurality of production lines, and a staff change in a production line on the day are registered. In a business entity in which a certification system is established for workers, the quality of the product is more likely to be maintained. Therefore, in a case where there is a certification system, the score is made lower than in a case where there is no certification system. In a case where a worker is assigned multiple roles in a plurality of production lines, a defect is more likely to occur than in a case where the worker takes charge of only one production line. Therefore, in a case where multiple roles are assigned, the score is made higher than in a case where multiple roles are not assigned. As described above, weights may be adjusted in accordance with the additional factors related to workers.

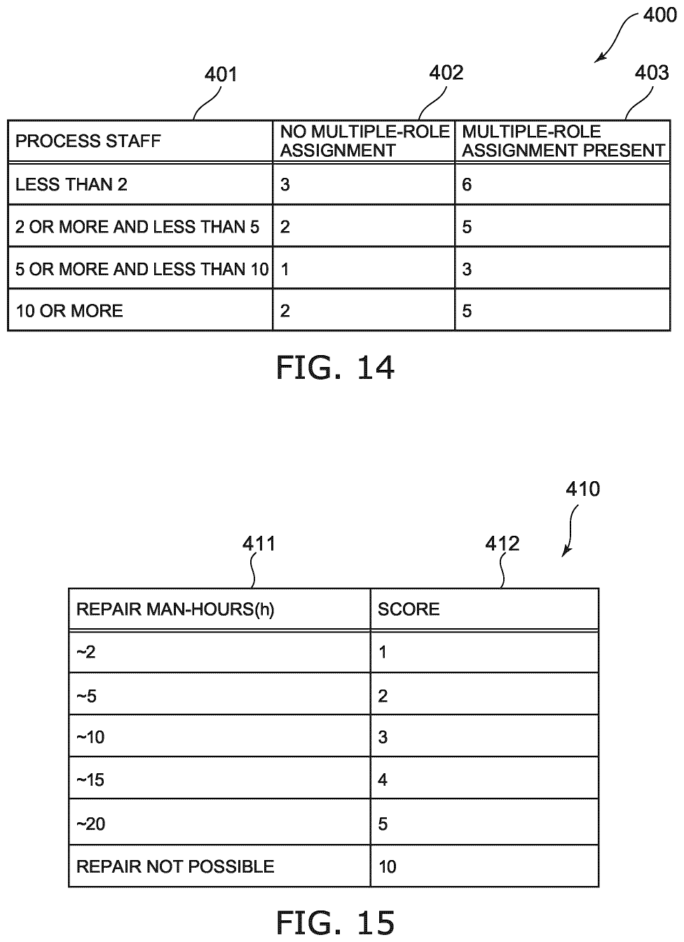

A table 400 shown in FIG. 14 includes process staff 401, a score 402, and a score 403. A score based on both the number of staff members in a process or a production line and the presence or absence of multiple-role assignment may be used. Multiple-role assignment can reduce the number of staff members, however, multiple-role assignment to a large number of people requires cooperation between a plurality of workers, and omissions or duplication are more likely to occur, which leads to difficulty in management. Taking into consideration the above-described matters, scores are set in accordance with the presence and absence of multiple-role assignment, on a staff-by-staff basis in the table 400.

A table 410 shown in FIG. 15 includes a repair man-hours 411 and a score 412. The repair man-hours 411 indicates a man-hours necessary for a repair of a defect. The score 412 indicates a score set for each repair man-hours. Desirably, as a man-hours necessary for a repair of a defect is longer, the frequency of the occurrence of the defect is lower. Therefore, as the repair man-hours is longer, the score is made higher. For example, for each cause registered in the first database, a man-hours necessary for the repair is registered in advance. In accordance with the registered repair man-hours, a score related to the repair man-hours of the cause is set.

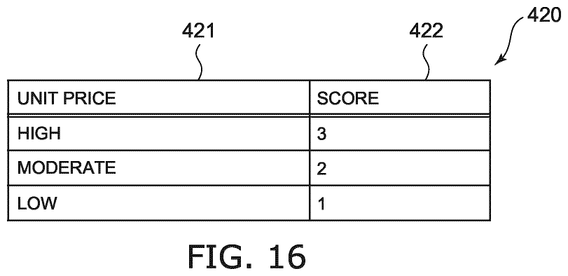

A table 420 shown in FIG. 16 includes a unit price 421 and a score 422. The unit price 421 indicates the unit price of a component of the product. In the example in FIG. 16, ranked unit prices are indicated. For example, as the unit price 421, the unit price of a printed circuit board is used. The score 422 indicates scores set for respective unit prices 421. Desirably, as the unit price is higher, the frequency of the occurrence of a defect in the product is lower. Therefore, as the unit price is higher, the score is made higher. For example, a list of components used in the product is prepared in advance. In the list, components related to defect modes and components for which scores are set are specified in advance. A consolidated model is generated for each component and for each defect mode. In accordance with the unit price of each component, the sequence of individual models in the consolidated model can differ.

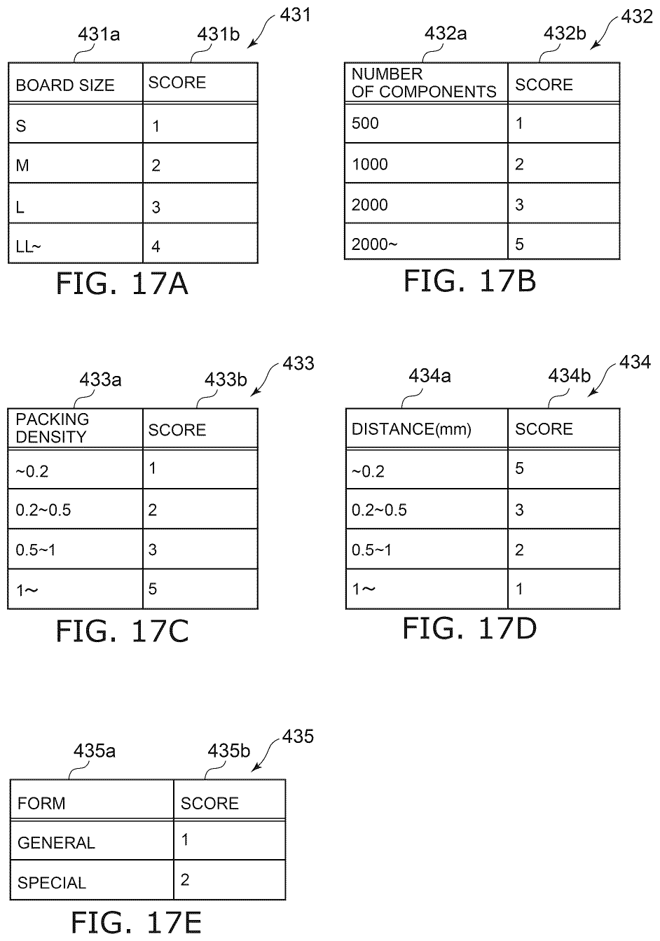

Scores may be set in accordance with the difficulty of producing the product. A table 431 shown in FIG. 17A includes a board size 431a and a score 431b. The board size 431a is the size of a printed circuit board or a printed wiring board. As the board size is larger, the difficulty of production increases. Therefore, as the board size is larger, the score is made higher. A table 432 shown in FIG. 17B includes a number of components 432a and a score 432b. The number of components 432a indicates the number of components set on one board. As the number of components is larger, the difficulty of production increases. Therefore, as the number of components is larger, the score is made higher. A table 433 shown in FIG. 17C includes a packing density 433a and a score 433b. The packing density 433a indicates the packing density on one board. As the packing density is higher, the difficulty of production increases. Therefore, as the packing density is higher, the score is made higher. A table 434 shown in FIG. 17D includes a distance 434a and a score 434b. The distance 434a indicates the average value or minimum value of the distances between components included in one board. As the distance is narrower, the difficulty of production increases. Therefore, as the distance is narrower, the score is made higher. A table 435 shown in FIG. 17E includes a form 435a and a score 435b. The form 435a indicates whether the form of a board to be used is general or special. In a case where a board in a special form is used, the difficulty of production increases compared to a case where a board in a general form is used. Therefore, in the case where a board in a special form is used, the score is made higher than in the case where a board in a general form is used.

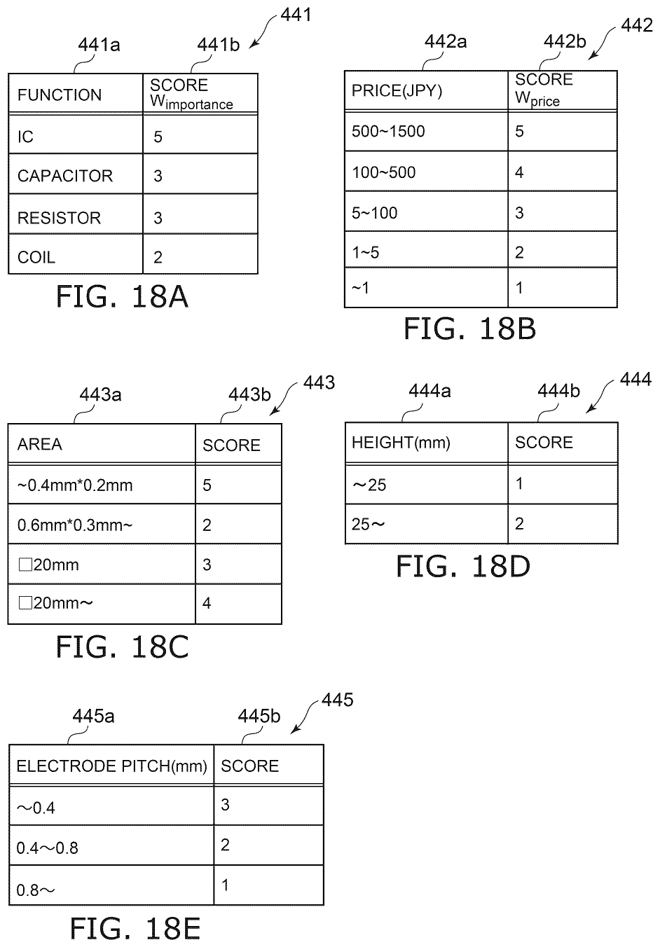

Scores may be set in accordance with the specifications of components included in the product. A table 441 shown in FIG. 18A includes a function 441a and a score 441b. The function 441a indicates the function of a component. A component having a more advanced function has a larger influence on the quality of the product, and therefore, the score is made higher. A table 442 shown in FIG. 18B includes a price 442a and a score 442b. The price 442a indicates the price of a target component. Desirably, as the price is higher, the frequency of the occurrence of a defect related to the component is lower. Therefore, as the price is higher, the score is made higher. A table 443 shown in FIG. 18C includes an area 443a and a score 443b. The area 443a indicates the area of a target component. As the area of a component is smaller, the difficulty of mounting the component increases. As the area is larger, the difficulty decreases, however, the difficulty increases again when the area exceeds a certain area. Therefore, the score of an intermediate area is made lower. A table 444 shown in FIG. 18D includes a height 444a and a score 444b. The height 444a indicates the height of a target component. As a component is higher, the difficulty of mounting the component increases. Therefore, as a component is higher, the score is made higher. A table 445 shown in FIG. 18E includes an electrode pitch 445a and a score 445b. The electrode pitch 445a indicates the electrode pitch in a target component. As the pitch is narrower, the difficulty of production increases. Therefore, as the pitch is narrower, the score is made higher. For example, a score Sc0 according to the specifications of a component is determined with the following expression by using a score Sc1 set as the score 441b, a score Sc2 set as the score 442b, a score Sc3 set as the score 443b, a score Sc4 set as the score 444b, and a score Sc5 set as the score 445b.

$$Sc 0 = Sc 1 \times Sc 2 \times ( Sc 3 + Sc 4 + Sc 5 )$$

Scores related to the production environment of the product may be set. For example, a score may be set for each of the temperature, the humidity, the air volume, the air speed, the presence or absence of an ionizer, and the result of measurement by a particle counter. In a specific example, in a case where the product is produced in a space where there are fewer particles, the possibility of the occurrence of a defect is lower than in a case where the product is produced in a space where there are more particles. Therefore, the score is made lower.

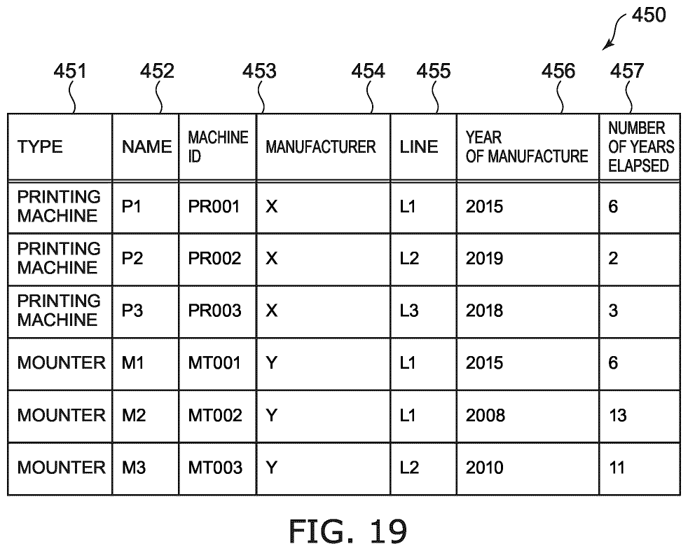

FIG. 19 to FIG. 22 show example data usable in the processing method according to the embodiment.

The tables shown in FIG. 19 to FIG. 22 can be referred to for, for example, the relationship between a line and an apparatus used in the line, the relationship between a product and a process in the production line, and association of data between the first database and the second database described above. The tables shown in FIG. 19 to FIG. 22 may be stored in any of the first to third databases or may be stored in a database different from these databases.

A table 450 shown in FIG. 19 includes a type 451, a name 452, a machine ID 453, a manufacturer 454, a line 455, a year of manufacture 456, and a number of years elapsed 457. The type 451 indicates the type of an apparatus used in a line. The name 452 indicates the name of the apparatus (its assumed name in the line). The machine ID 453 is characters for identifying the apparatus. The line 455 indicates the line in which the apparatus is provided. The year of manufacture 456 is the year in which the apparatus was manufactured. As the year of manufacture 456, the month and day may be further registered as more details. The number of years elapsed 457 indicates the number of years elapsed since the manufacture of the apparatus. By using the table 450 shown in FIG. 19, the number of years elapsed 341 and the scores 342 to 344 in the table 340 shown in FIG. 8 can be calculated. Alternatively, instead of the table 340 shown in FIG. 8, a mathematical expression for calculating a score according to the number of years elapsed may be stored in the third database.

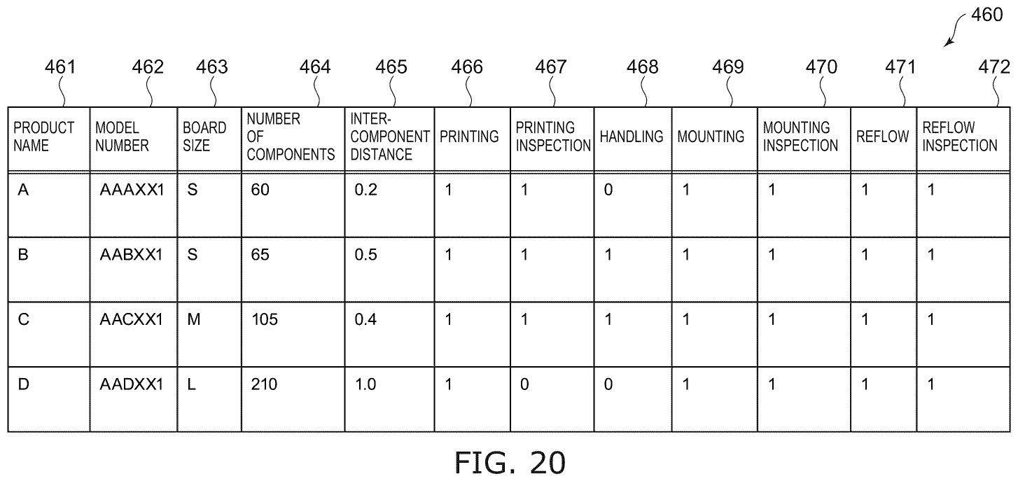

A table 460 shown in FIG. 20 includes a product name 461, a model number 462, a board size 463, a number of components 464, an inter-component distance 465, and pieces of data 466 to 472 indicating the presence or absence of respective processes. The model number 462 is a character string indicating the model of the product. The board size 463, the number of components 464, and the inter-component distance 465 correspond to the board size 431a, the number of components 432a, and the distance 434a shown in FIGS. 17A, 17B, and 17D. For the pieces of data 466 to 472, “0” indicates that the process indicated in the header is not present in the production line of the product. “1” indicates that the process indicated in the header is present in the production line of the product. The table 460 shown in FIG. can be used to derive scores in the tables shown in FIG. 17A to FIG. 18E.

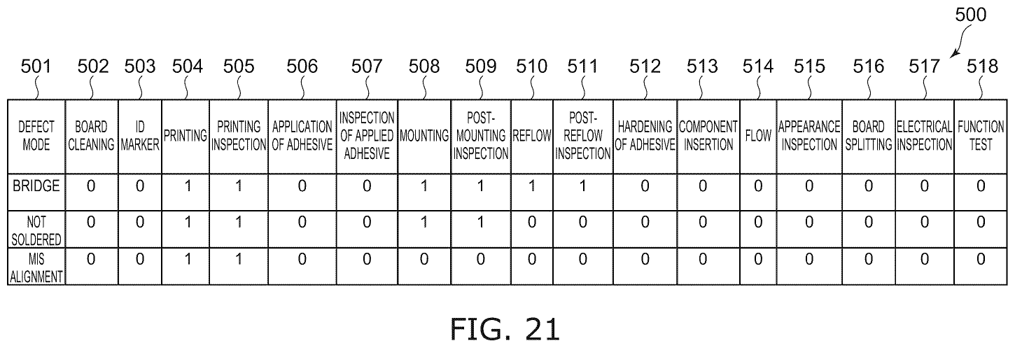

A table 500 shown in FIG. 21 includes a defect mode 501 and pieces of data 502 to 518. The defect mode 501 corresponds to the defect mode 110 registered in the first database 100. The pieces of data 502 to 518 indicate the presence of a defect mode in respective processes. “0” indicates that, in the process indicated in the header, the defect mode does not occur. “1” indicates that, in the process indicated in the header, the defect mode can occur.

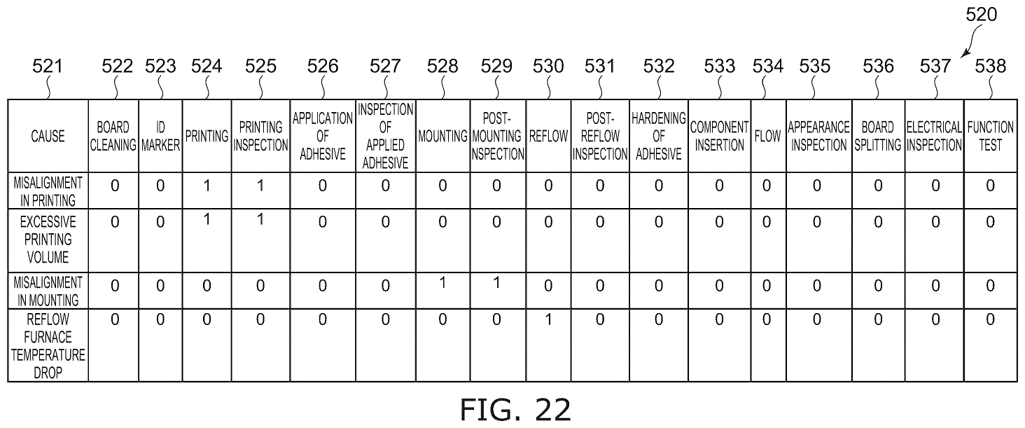

A table 520 shown in FIG. 22 includes a cause 521 and pieces of data 522 to 538. The cause 521 corresponds to the cause 120 registered in the first database 100. The pieces of data 522 to 538 indicate the presence of a cause related to a defect mode in respective processes. “0” indicates that, in the process indicated in the header, the cause is not related to a defect mode. “1” indicates that, in the process indicated in the header, the cause can be related to a defect mode.

By using the tables 500 and 520 shown in FIG. 21 and FIG. 22, the defect mode 110 and the cause 120 stored in the first database 100 can be associated with the cause 210 and the individual model 220 stored in the second database 200.

In addition, a table indicating, for example, the name of each product, the processes of each product, and the sequence of the processes may be used.

The weights in the first database are set on the basis of at least any of the pieces of data in the third database described above. That is, the weights in the first database are determined by using one or more selected from a first group consisting of a score based on the number of occurrences of each cause, a score based on the configuration of the production line, a score based on the scale of staff at the production site, a score based on the repair man-hours for each defect mode, a score based on the price of a component, a score based on the difficulty of production of the product, a score based on the type of a component included in the product, a score based on the production environment of the product, a score based on the number of years elapsed of the manufacturing equipment for the product, and a score based on the time of the occurrence of each cause. When one or more scores selected from the first group are used, the weights can be more appropriately set. As a result, a consolidated model that is more effective in remedying a defect can be generated.

For example, a weighting model that outputs the weight of each cause in response to an input of the score of each piece of data is prepared in advance. The score of each piece of data stored in the third database is input into this model to obtain the weight of each cause. For example, the model includes a neural network. The scores of a plurality of pieces of data are respectively input into a plurality of terminals of the input layer. The weights of a plurality of causes are respectively output from a plurality of terminals of the output layer.

For each inter-node weight in the neural network, an initial value is set by a user or in accordance with a predetermined rule. Each time a consolidated model based on the weights output from the weighting model is executed, the user inputs feedback on the consolidated model. Alternatively, a system may automatically input feedback on the basis of the result of determination by, for example, an inspection machine or the neural network. For example, the feedback includes a measure with which a defect mode can be actually remedied. The weighting model is trained on the basis of the feedback to output a greater weight for the measure.

Alternatively, the neural network may be trained in advance by supervised learning. To train the neural network, a plurality of pieces of learning data are used. Each piece of learning data includes input data and teaching data. The input data includes the score of each piece of data to be input into the input layer. The teaching data includes the weight of each cause corresponding to the input data. The neural network is trained to output teaching data in response to an input of the input data.

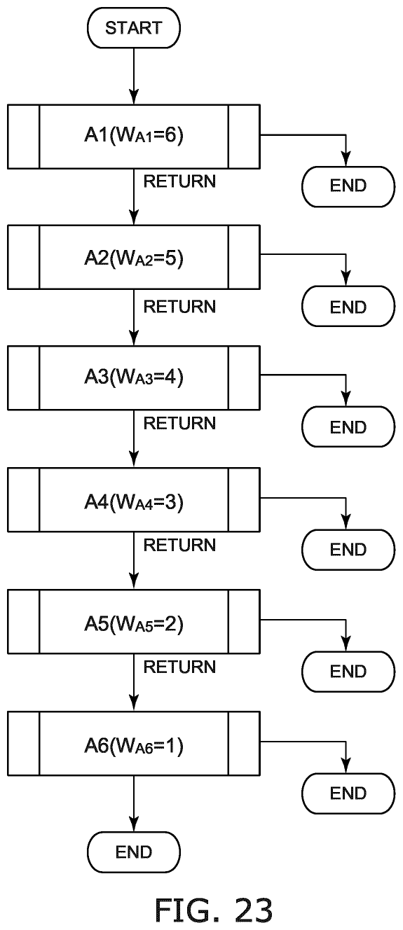

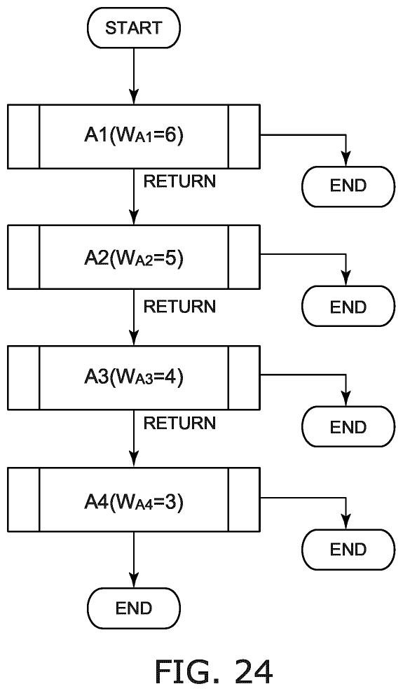

FIG. 23 and FIG. 24 are schematic diagrams illustrating consolidated models. In FIG. 23 and FIG. 24, the specific details of each individual model are omitted.

In the consolidated model shown in FIG. 23, individual models A1 to A6 are arranged for a certain defect mode. WA1 to WA6 respectively indicate the weights of causes corresponding to the individual models A1 to A6. Whether to execute each individual model may be determined in accordance with the weight. In an example, a threshold value for the weights is set to 2. Only an individual model whose corresponding weight exceeds 2 is executed. Upon execution of the consolidated model, the individual models are executed in sequence from the individual model A1, however, the individual models A5 and A6 whose corresponding weights are less than or equal to 2 are not executed.

Alternatively, the consolidated model may be formed of only individual models whose corresponding weights exceed the threshold value. In the consolidated model shown in FIG. 24, the individual models A1 to A4 are arranged. This consolidated model does not include the individual models A5 and A6. As a result, the individual models A5 and A6 whose corresponding weights are less than or equal to 2 are not executed. In both the examples in FIG. 23 and FIG. 24, during the execution of the consolidated model, check data in the individual models A5 and A6 are not input.

When an individual model to be executed is selected in accordance with the weight, only an individual model having a high importance level is executed. For example, the execution of an individual model that is less likely to remedy the defect mode is avoided, and effort made by the worker for a check upon the execution of the consolidated model can be reduced.

The number of individual models to be executed can be controlled by adjusting scores related to the weights of all causes in, for example, the tables 360 to 400 shown in FIG. 10 to FIG. 14. For example, as the scores in the table 360, 390, or 400 increase or as the scaling factor in the table 370 or 380 increases, the weight of each cause uniformly increases. Accordingly, the number of individual models to be executed increases. For example, scores related to the weights of causes are adjusted in accordance with manpower with which consolidated models can be executed. A company having a plurality of manufacturing bases can standardize the scores in the company by not using the table 360, or can adjust the scores in accordance with the capacity of each base by using the table 360.

The advantages of the embodiment will be described.

Upon the occurrence of a defect in a product, a measure for remedying the defect is generally implemented. When a person considers the measure, the details of the measure depend on, for example, the experience and knowledge of the person. Therefore, the measure may vary. It is possible to prepare in advance a list of possible measures and implement the listed measures upon the occurrence of a defect. In this case, the sequence in which the measures are implemented affects the time taken to remedy. That is, as measures effective in remedying are implemented more quickly, the defect is remedied in a shorter time. However, the sequence depends on, for example, the person's experience and knowledge. The determination of the sequence may be troublesome to the person.

Specifically, many causes are present for one defect mode depending on the product. A common cause may be present for different defect modes. Therefore, it is not easy for a person to appropriately determine measures corresponding to the defect mode.

For these issues, in the processing method according to the embodiment, individual models are first referred to. The individual models indicate measures against the causes of defect modes in the product and are prepared in advance. Next, for each of the plurality of defect modes, a consolidated model is generated. The consolidated model is generated by rearranging and connecting a plurality of individual models. At this time, the sequence of the plurality of individual models is determined in accordance with a plurality of weights respectively set for a plurality of causes. These processes can be performed by a computer.

According to the embodiment, consolidated models are generated for respective defect modes. Therefore, when any of the defects occurs, a consolidated model appropriate for the defect mode can be executed. Each consolidated model is generated by rearranging a plurality of individual models in accordance with weights indicating importance levels or effectiveness. Therefore, the sequence of the individual models does not depend on, for example, the knowledge and experience of the person. With the generated consolidated model, individual models that are more effective in remedying are executed more quickly, and the time taken to remedy can be reduced. Further, a plurality of consolidated models are generated by a computer, which can reduce effort made by a person.

According to the embodiment, a consolidated model that is effective in remedying a defect can be automatically generated.

The embodiment is specifically effective for, for example, a product produced through a board mounting process and a product produced through a resin molding process or a die-casting process. In these process, various defects can specifically occur. The causes of the defects range widely. Therefore, determination of measures against the defects by a person is difficult. According to the embodiment, for defects in the products produced through the above-described processes, effective measures can be automatically generated.

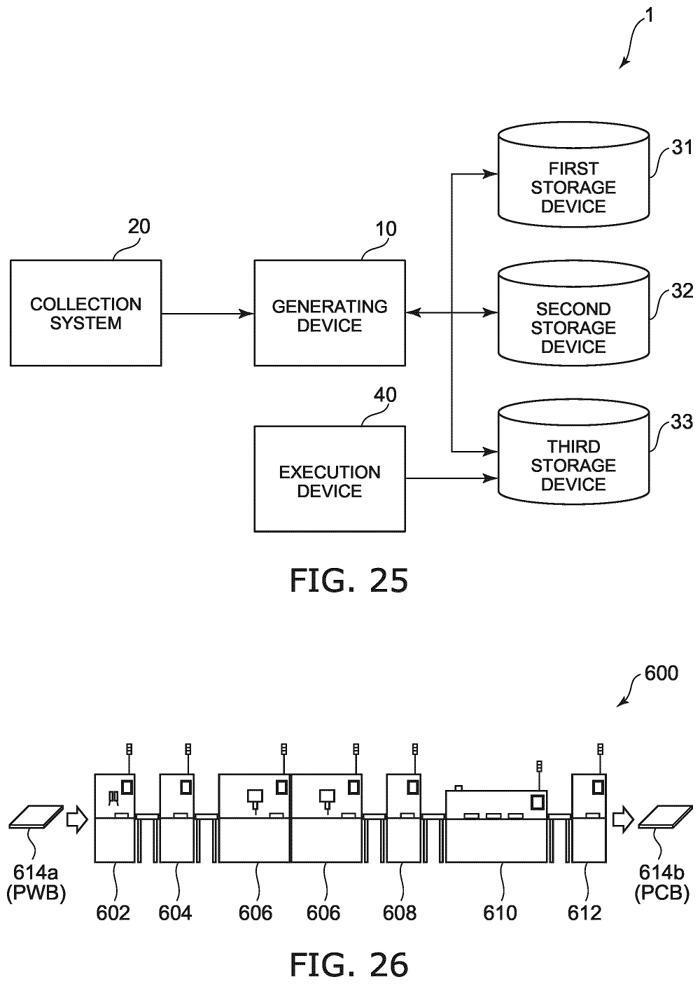

FIG. 25 is a schematic diagram showing a processing system according to the embodiment.

The processing method M1 shown in FIG. 1 can be performed by a processing system 1 shown in FIG. 25. The processing system 1 includes a generating device 10, a collection system 20, a first storage device 31, a second storage device 32, a third storage device 33, and an execution device 40.

The generating device 10 performs the flowchart shown in FIG. 1 to generate a consolidated model. The execution device performs at least some of the steps in the consolidated model. The generating device 10 and the execution device 40 are computers. The generating device 10 may have the functions of the execution device 40. The collection system 20 collects quality data. The collection system 20 includes an inspection machine provided in each production line. For example, some of the functions of a manufacturing execution system (MES) can be used as the collection system 20. The first storage device 31 to the third storage device 33 respectively store the first database to the third database. The generating device 10, the collection system 20, the first storage device 31 to the third storage device 33, and the execution device 40 are connected to each other via wired communication, wireless communication, or the Internet.

### Example

FIG. 26 is a schematic diagram showing a manufacturing line for a mounted board.

As shown in FIG. 26, for example, a manufacturing line 600 for a mounted board includes a printing machine 602, a printing inspection machine 604, a mounter 606, a mounting inspection machine 608, a reflow furnace 610, and an appearance inspection machine 612, and processes a board 614a. The board 614a is a PWB. The board 614a, which is a PWB, is put into the manufacturing line 600, and a board 614b, which is a mounted board (printed circuit board: PCB) on which electronic components are mounted, is manufactured.

The printing machine 602 prints solder paste on the board 614a. The printing inspection machine 604 captures an image of the board 614a on which the solder paste has been printed. The printing inspection machine 604 checks to see, from the image, if the solder paste has been appropriately printed.

The mounter 606 mounts electronic components on the board 614a. In the illustrated example, a plurality of mounters 606 each mount a plurality of electronic components on one board 614a. The mounting inspection machine 608 captures an image of the board 614a on which the electronic components have been mounted. The mounting inspection machine 608 checks to see, from the image, if the electronic components have been appropriately mounted.

The reflow furnace 610 heats the board 614a to make the solder paste melted. When the temperature of the board 614a drops, the solder paste solidifies, and the mounted electronic components are electrically connected to the solder. Accordingly, the board 614b is manufactured. The appearance inspection machine 612 captures an image of the board 614b, which has been soldered. The appearance inspection machine 612 checks to see, from the image, if the electronic components have been appropriately soldered.

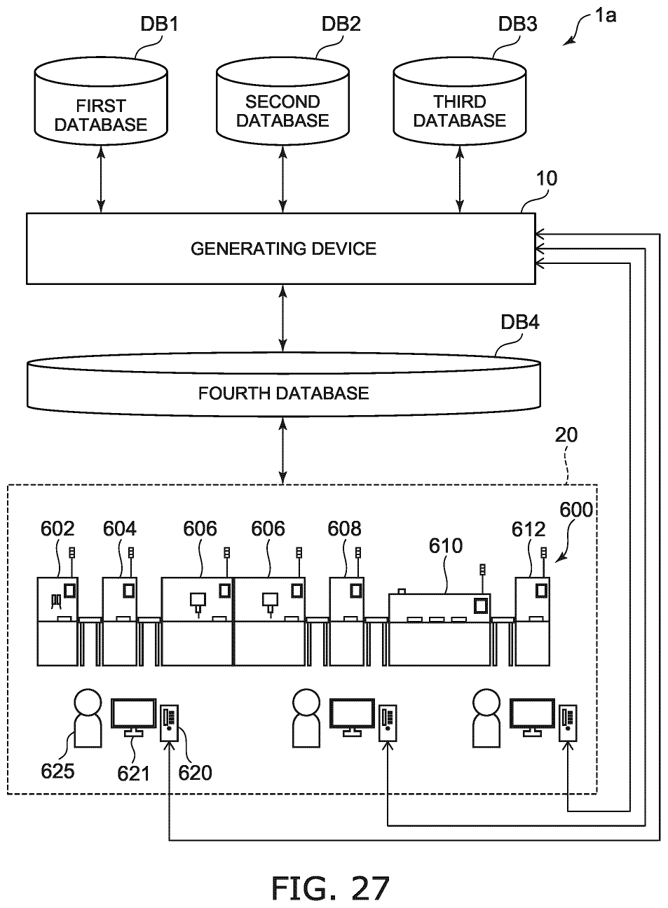

FIG. 27 is a schematic diagram showing a processing system according to an example.

As shown in FIG. 27, for example, a processing system 1a is applied to the manufacturing line 600. The processing system 1a includes the generating device 10, the collection system 20, and a first database DB1 to a fourth database DB4.

The manufacturing line 600 and a processing device 620 function as the collection system 20. Specifically, the printing machine 602, the mounter 606, and the reflow furnace 610 save, in the fourth database DB4 via a network, setting conditions set in advance for processing the board 614a or processing conditions measured during the processing. For example, the printing machine 602 saves, for example, the amount of printed solder, the pressure and temperature upon printing, and the moving speed of the print head in the fourth database DB4. The reflow furnace 610 saves, for example, the temperature and pressure upon reflow in the fourth database DB4.

The printing inspection machine 604, the mounting inspection machine 608, and the appearance inspection machine 612 save, in the fourth database DB4 via a network, for example, identification data (ID) of the inspected board 614a or 614b, the times when inspection results are obtained, the IDs of the inspection machines, inspection conditions, inspection results, and quality data based on the inspection results. For example, the printing inspection machine 604 and the mounting inspection machine 608 each save, in the fourth database DB4, for example, the amounts of shifts of the positions of solder and electronic components from standard positions, and inspection results based on the amounts of shifts. The appearance inspection machine 612 saves, in the fourth database DB4, for example, the amount of solder protruding from an electronic component and an inspection result based on the amount of protrusion.

Each inspection machine transmits obtained data to the corresponding processing device 620 provided for the inspection machine. The processing device 620 can display the received data on a monitor 621 (display device). Each inspection machine is assigned an inspector 625. The inspector 625 can check on the monitor 621, the data obtained from the inspection machine. When a defect in the board 614a or 614b is found from the data from the inspection machine, the inspector 625 may use the processing device 620 to save, in the fourth database DB4, data regarding the defect.

In the first database DB1, a plurality of defect modes and a plurality of causes are stored. In the second database DB2, a plurality of causes and a plurality of individual models are stored. The generating device 10 accesses the first database DB1 and the second database DB2 and generates in advance a consolidated model from data in the first database DB1 and in the second database DB2. The generating device 10 accesses the fourth database DB4 and obtains pieces of data saved in the fourth database DB4. The generating device 10 associates the obtained pieces of data with each other as appropriate. For example, the generating device 10 associates obtained pieces of data for each inspection machine. The generating device 10 may associate, for each of the board 614a or 614b, pieces of data obtained in the processing of the board 614a or 614b.

The generating device 10 determines whether the obtained pieces of data include a piece of data indicating a defect in the board 614a or 614b. When a piece of data indicating a defect in the board 614a or 614b is present, the generating device 10 executes a consolidated model corresponding to a defect mode indicated by the piece of data. That is, in the processing system 1a, the generating device 10 also has the functions of the execution device 40 shown in FIG. 25.

For example, the processing device 620 operates as a client, and the generating device 10 operates as a server on a network. When the consolidated model is executed by the generating device 10, measures of the respective individual models are displayed on the monitor 621. The measures are implemented by, for example, the inspector 625. The measures may be implemented by an engineer who is in charge of, for example, maintenance. An example in which the measures are implemented by the inspector 625 will be described below. The inspector 625 inputs the results of the measures into the processing device 620. The processing device 620 transmits the input data to the generating device 10.

The generating device 10 saves the data obtained during the execution of the consolidated model in the third database DB3. When saving of the data in the third database DB3 results in a change in a weight in the first database DB1, the generating device 10 determines whether the consolidated model needs to be updated. When the consolidated model needs to be updated, the generating device 10 generates a new consolidated model.

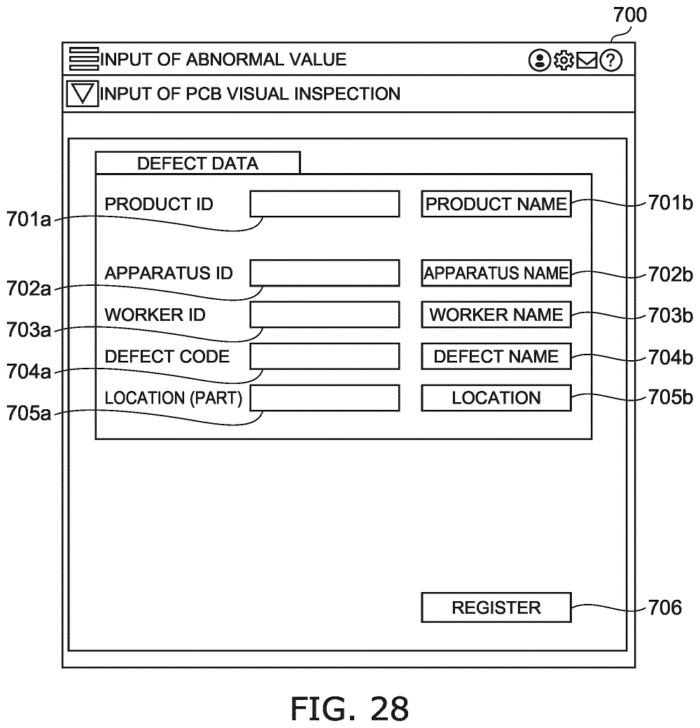

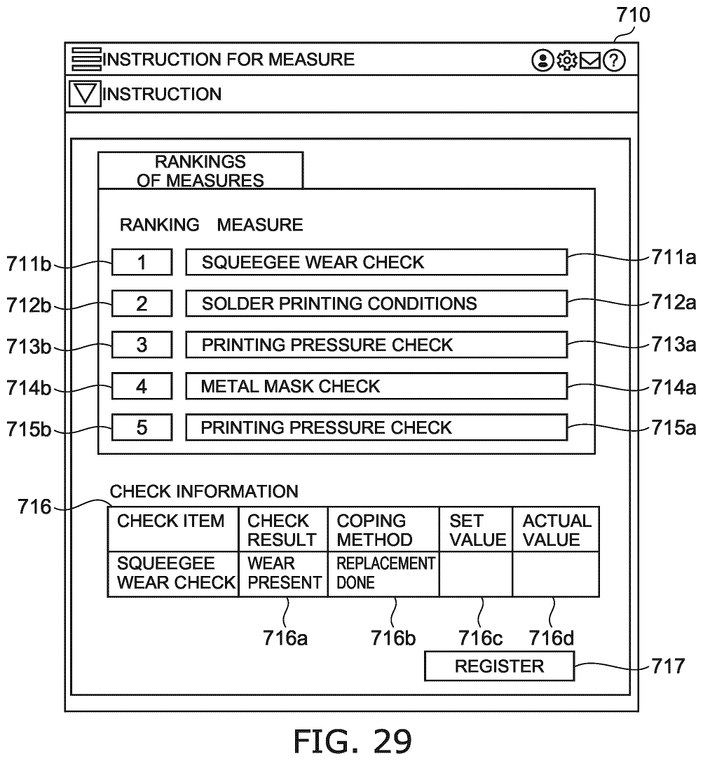

FIG. 28 shows example output by the processing device according to the embodiment. FIG. 29 to FIG. 34 show example output by the generating device according to the embodiment. When a defect in the board 614a or the board 614b is identified by an inspection machine, for example, the inspector inputs data onto a user interface (UI) 700 shown in FIG. 28. On the UI 700, input fields 701a to 705a, icons 701b to 705b, and an icon 706 are displayed. The inspector uses an input device of the processing device to input data while checking the UI 700.

Into the input field 701a, the ID of a product (board) is input. The inspector can make a list of the names of products be displayed by clicking on the icon 701b and can select an ID from the list. Instead of displaying the list, the processing device 620 may accept an input from an ID reader connected to the processing device 620. The reader is, for example, a bar code reader, a QR code (registered trademark) reader, a color code reader, or an IC tag reader.

Into the input field 702a, the ID of an apparatus, such as the printing machine 602, the mounter 606, or the reflow furnace 610, is input. The inspector can make a list of the names of apparatuses be displayed by clicking on the icon 702b and can select an ID from the list. Instead of displaying the list, the processing device 620 may accept selection of a manufacturing line. For example, the inspector can collectively select the IDs of apparatuses by selecting the ID of a manufacturing line. The ID of an apparatus may be automatically selected by referring to a predetermined line or process schedule on the basis of the product model number of the board 614a or 614b.

Into the input field 703a, the ID of the worker (inspector) is input. The inspector can make a list of the names of workers be displayed by clicking on the icon 703b and can select an ID from the list.

Into the input field 704a, a code for identifying the defect mode is input. The inspector can make a list of the names of defect modes be displayed by clicking on the icon 704b and can select a code from the list.

Into the input field 705a, the location where the defect occurs in the board 614a or 614b is input. The inspector can make a list of locations be displayed by clicking on the icon 705b and can select a location from the list.

After inputting data into the input fields 701a to 705a, the inspector clicks on the icon 706 to complete registration of the data. The generating device 10 accepts the registered data. The generating device 10 executes a consolidated model corresponding to the defect mode identified with the defect code.

The generating device 10 makes a UI 710 shown in FIG. 29 be displayed on the monitor 621. On the UI 710, individual models 711a to 715a included in the executed consolidated model are displayed as the rankings of measures. The rankings of measures indicate the sequence of the individual models included in the consolidated model generated by using weights. When the inspector clicks on any of the individual models 711a to 715a, check information 716 in the individual model can be displayed. In the illustrated example, information regarding the individual model 711a is displayed. For a highly ranked individual model in the rankings of already implemented measures, a check result and a coping method that have been registered are displayed. When individual models are arranged in series in a consolidated model as shown in FIG. 4, the rankings of all measures are not displayed. Already implemented individual models and individual models to be coped with are displayed. In an example, it is assumed that an individual model related to “insufficient printing volume of solder” is highly ranked in the rankings of measures on the basis of the weight. In this case, data of the printing inspection machine 604 is referred to, and when the printing inspection result of a component in which the defect occurs has no problem, it is determined that the defect does not correspond to “insufficient printing volume of solder” even when the individual model is ranked high in the sequence based on the weights, and the individual model is not displayed in the rankings of measures.

Upon the execution of a consolidated model, at least some of the individual models may be processed in parallel. When individual models are processed in parallel, the rankings of all measures are displayed, and the measures are checked or implemented in sequence from a highly ranked individual model. Whether to process individual models in a consolidated model in series or in parallel may be allowed to be switched by mode switching by software in accordance with the state of processing of the consolidated model. The switching may be automatically performed by the software or may be selected by the user. As a criterion of the mode switching, for example, the number of individual models under execution or the usage rate of the CPU or a memory, which is an index of the processing speed of the generating device 10, can be used. When a consolidated model performs serial processing, measures can be displayed quickly and implemented earlier, and when a consolidated model performs parallel processing, all measures can be collectively displayed.

The details (measure) displayed in the check information 716 are implemented. As the check item, the details of actual work may be displayed in addition to the name of the individual model. For example, in a case of a squeegee wear check, an instruction is displayed to urge the inspector to stop the printing machine, wipe squeegee paste, and visually check to see if deformation due to wear is present. The measures are implemented by, for example, the inspector. The measures may be implemented by an engineer who is in charge of, for example, maintenance. The inspector inputs the results of the check into input fields 716a to 716d and clicks on an icon 717 to register the data. The generating device 10 receives the registered check data. The inspector implements the measures indicated by the individual models in accordance with the displayed sequence of 711b to 715b until a cause of the defect is identified.

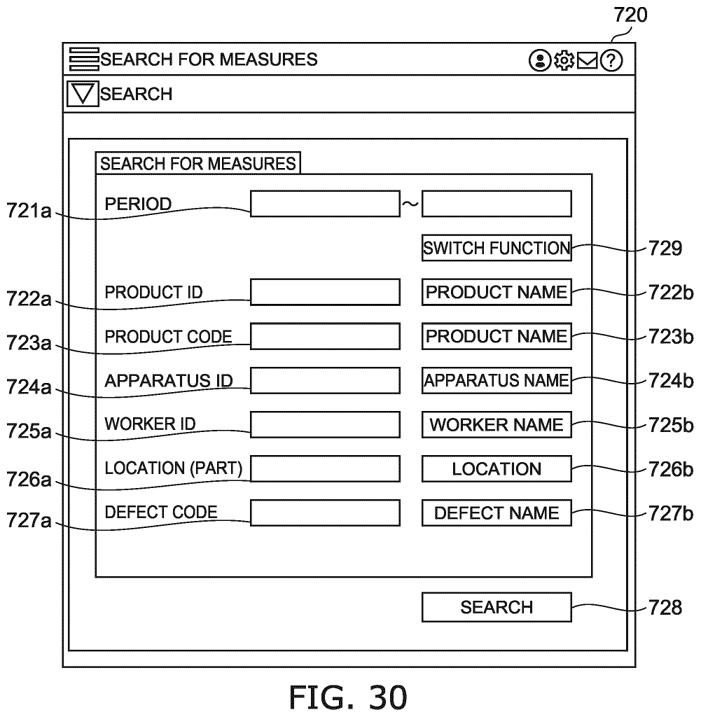

On the monitor 621, a screen for narrowing down measures (individual models) to be displayed may be displayed. The generating device 10 makes a UI 720 shown in FIG. 30 be displayed on the monitor 621. On the UI 720, input fields 721a to 727a, icons 722b to 727b, and an icon 728 are displayed.

Into the input field 721a, a period is input. When a period is input, a search is carried out for products to which individual models are applied during the input period, measures implemented for the products, and check results and coping methods in the implemented measures. The search results include a case where no measures are implemented, and in this case, a check result or a coping method need not be displayed. Into the input field 722a, a product ID is input. When a product ID is input, a search is carried out for individual models that were effective in the past for a product having the product ID. Similarly, into the input fields 723a to 726a, a product code, an apparatus ID, a worker ID, and a location can be input respectively. A search is carried out for individual models that were effective in the past for products related to the input data. The inspector can make a list of the names of products, apparatuses, workers, or locations be displayed by clicking on the icons 722b to 726b and can select an ID or a code from the list.

The inspector can input a defect code into the input field 727a. When a defect code is input, a consolidated model corresponding to a defect mode identified with the defect code is displayed. The inspector can make a list of the names of defect modes be displayed by clicking on the icon 727b and can select a code from the list.

Input into all of the plurality of items shown on the UI 720 need not necessarily be performed. Input into one or more of the plurality of items needs to be performed. After inputting conditions for a search, the inspector clicks on the icon 728. The generating device 10 accepts the search conditions and makes measures (individual models) that match the search conditions be displayed on the monitor 621.

Alternatively, when a period is input into the input field 721a, the generating device 10 may calculate the weight of each cause on the basis of, for example, quality data and check data obtained during the input period. The generating device 10 rearranges the individual models in accordance with the calculated weights to generate a new consolidated model. For example, when a most recent specific period is specified, a consolidated model effective for a defect mode having occurred most recently can be generated. It may be allowed to apply a new consolidated model to the result of execution of a past consolidated model so as to display an instruction for a measure again. When the new consolidated model is applied to the past result, a measure that is not displayed in the past consolidated model can be implemented. In this case, instructions for measures by the past consolidated model and individual models and the result of execution are also stored as a record.

As shown in FIG. 30, an icon 729 for switching a function to be executed in response to an input of a period into the input field 721a between the above-described functions may be displayed on the UI 720. When clicking on the icon 729, the user can switch the function to be executed when a period is input into the input field 721a. That is, when a period is input, switching between the function of searching for, for example, products to which individual models are applied and measures and the function of generating a consolidated model corresponding to the period can be performed.

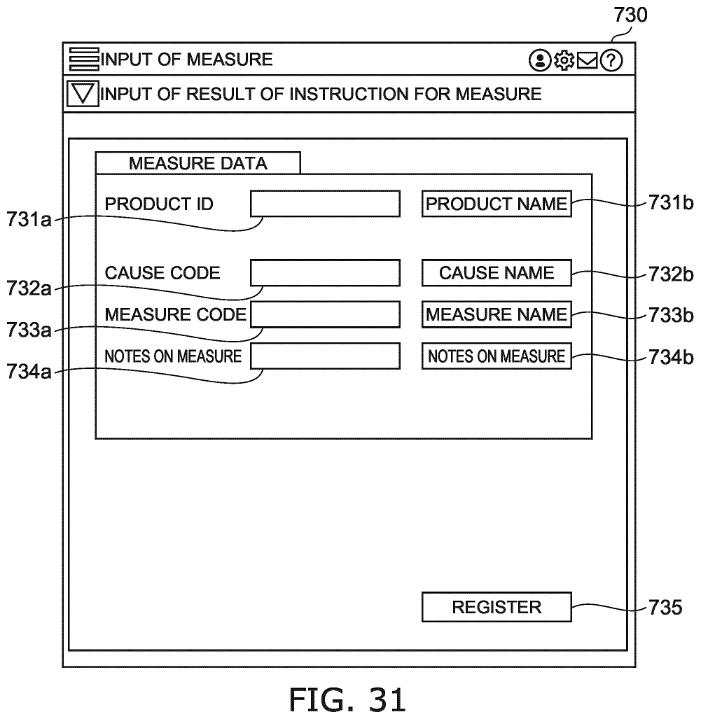

When a cause of the defect is identified, the inspector inputs the result of execution of the consolidated model into the generating device 10. The generating device 10 makes a UI 730 for inputting the result of execution of the consolidated model be displayed on the monitor 621 as shown in FIG. 31. On the UI 730, input fields 731a to 734a, icons 731b to 734b, and an icon 735 are displayed.

Into the input field 731a, a product ID is input. Into the input field 732a, the code of the cause of the defect is input. Into the input field 733a, the code of a measure effective for the defect mode upon the execution of the consolidated model is input. Into the input field 734a, a note on the effective measure is input. The inspector can make a list of the names of products, causes, or defect modes be displayed by clicking on the icons 731b to 733b and can select an ID or a code from the list. The inspector can refer to notes input in the past by clicking on the icon 734b.

The generating device 10 may automatically input a product ID, a cause code, and a measure code on the basis of the data presented in FIG. 29. After inputting necessary data, the inspector clicks on the icon 735. Accordingly, the input data is transmitted to the generating device 10. The generating device saves the received data in the third database DB3 as appropriate. The generating device 10 updates the consolidated model as necessary.

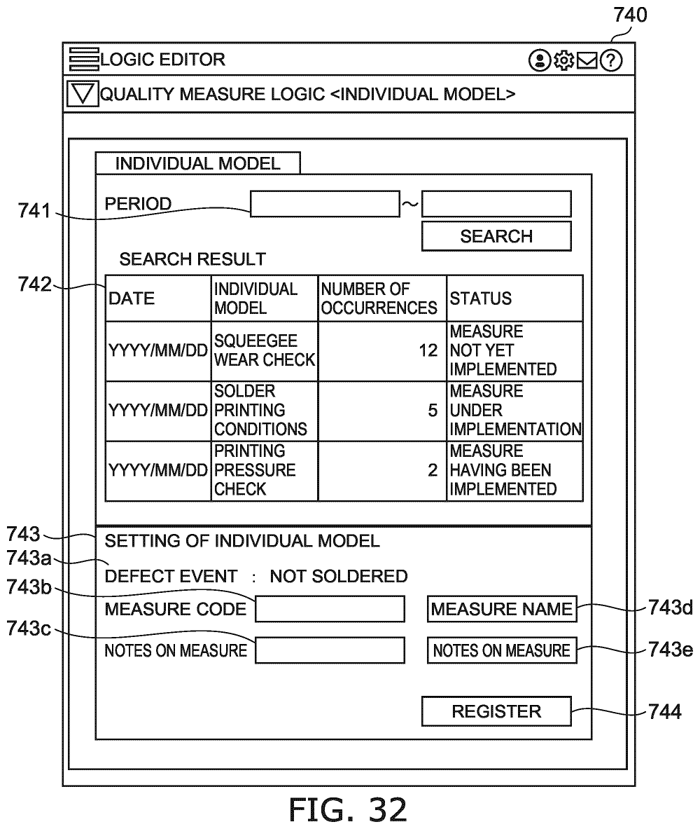

The generating device 10 may display a UI 740 for editing or checking an individual model as shown in FIG. 32. On the UI 740, an input field 741, a search result 742, an editing region 743, and an icon 744 are displayed. Into the input field 741, a period is input. A search is carried out for defect modes having occurred during the input period, and information regarding the causes of the defect modes are displayed in the search result 742.

In the search result 742, the name of an individual model, the date when the individual model was registered or updated, the number of occurrences indicating the number of cases where an instruction for the measure has been given by the individual model, and a status indicating the state of implementation of the instruction for the measure are displayed. For example, an individual model ID, the registerer of the individual model, and the code or name of a product to which the individual model is applied may be displayed. The status is displayed such that, for example, “measure not yet implemented” is displayed for an individual model whose measure is not yet implemented, “measure under implementation” is displayed for an individual model whose measure is being implemented, and “measure having been implemented” is displayed for an individual model whose measure is completed. “Measure not yet implemented” may be displayed when the measure is not yet implemented in any of the occurrences or “measure not yet implemented” may be displayed when the measure is not yet implemented in only one of the occurrences. The number of cases of “measure not yet implemented”, that of “measure under implementation”, and that of “measure having been implemented” may be displayed as a breakdown. In the edit region 743, a cause name 743a, input fields 743b and 743c, an icon 743d, and an icon 743e are displayed. Into the input field 743b, the code of an individual model to be set is input. Into the input field 743c, a note on the individual model to be set is input.

The user can make a list of the names of measures be displayed by clicking on the icon 743d and can select a measure from the list. The code of the selected measure is input into the input field 743b. In this case, an individual model that includes the selected measure can be checked and edited on the UI 740. The user can refer to notes input in the past by clicking on the icon 743e. The user is, for example, the inspector, the administrator of the manufacturing line, or the administrator of the processing system.

After completion of checking and editing of the individual model, the user clicks on the icon 744. Accordingly, the edited data is registered in the second database DB2.

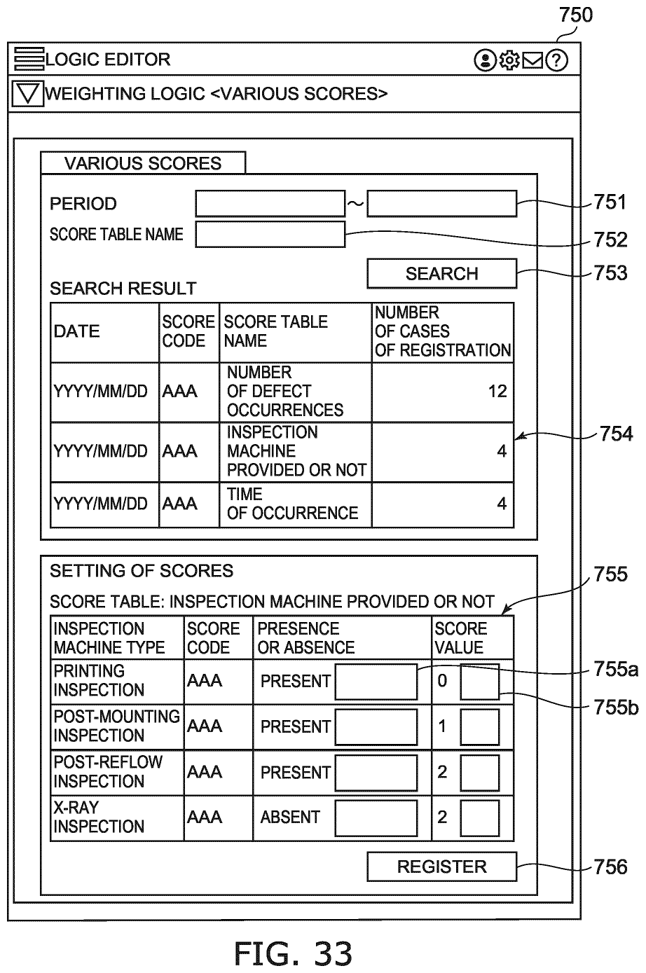

The generating device 10 may display a UI 750 for editing the score of each factor as shown in FIG. 33. On the UI 750, an input field 751, an input field 752, an icon 753, a search result 754, an edit region 755, and an icon 756 are displayed. Into the input field 751, a period is input. When a period is input, score tables registered during the input period are displayed as search results. The name of a score table may be directly specified in the input field 752. After inputting data into the input field 751 or 752, the user clicks on the icon 753. The search result 754 corresponding to the input data is displayed. In the search result 754, a date, a score code, a score table name, and the number of cases of registration are displayed. The date indicates the day when each score table was registered. The score code is a character string for identifying each score table. The number of cases of registration is the number of individual models that refer to the score table.

For example, in response to a click on any of the pieces of data displayed in the search result 754, data regarding the selected score table is displayed in the score edit region 755. In the illustrated example, an inspection machine type, a score code, the presence or absence, and a score value included in the score table are displayed in the edit region 755. The user can input data into an input field 755a or 755b in each line to edit a condition related to the presence or absence of each inspection machine type and a score value. After completion of editing, the user clicks on the icon 756. In response to the click on the icon 756, the edited scores are registered.

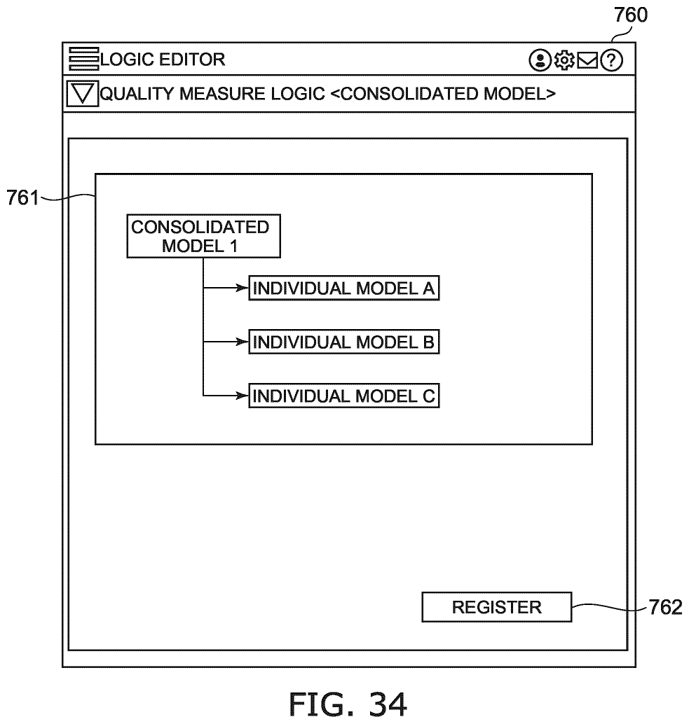

The generating device 10 may display a UI 760 for checking a consolidated model as shown in FIG. 34. In a display region 761 of the UI 760, the rankings of individual models in a certain consolidated model are displayed. With the display region 761 of the UI 760, the user can check the sequence in which the individual models are arranged in the certain consolidated model.

The user may be allowed to change the rankings of the individual models in the display region 761. After completion of the edit of the consolidated model, the user clicks on an icon 762. Accordingly, the edited data is registered.

In a manufacturing line for manufacturing a PCB, facilities respectively manufactured by a plurality of manufacturers are installed, and an engineer is assigned to each facility. For example, upon the occurrence of a defect, each engineer investigates the cause for a facility for which the engineer is responsible, and implements measures.

In an example, for the printing machine 602, for example, cleaning and a state check of the metal mask, cleaning and a fixing state check of the squeegee, cleaning and a state check of the backup plate, cleaning of the inside of the facility, a check of a temperature controller or an air conditioner, and greasing up of the apparatus driving unit are performed. For the mounter 606, for example, cleaning and a state check of the nozzle, maintenance of the head unit, cleaning and a state check of the feeder, cleaning of the inside of the facility, and greasing up of the apparatus drive unit are performed. For the reflow furnace 610, for example, flux removal and cleaning of the inside of the furnace, height adjustment and a state check of the labyrinth, cleaning and a state check of various sensors including an oxygen concentration meter, cleaning and a state check of the reflow pallet, cleaning and a state check of the fan, and a check of the temperature profile are performed.

When each engineer investigates the cause for a corresponding facility and implements measures, a lot of time is spent in total. It has been difficult to implement optimum measures against defects throughout the manufacturing line 600.

For this issue, with the processing system 1a, a consolidated model in which measures are arranged in a sequence for the manufacturing line 600 is generated for each defect mode. Upon the occurrence of a defect, measures are sequentially implemented in accordance with a consolidated model corresponding to the defect mode. For example, when the measures are implemented in accordance with the consolidated model, for example, a less effective measure or an unnecessary measure is less likely to be implemented. A cause of the defect mode can be found earlier and restoration of the manufacturing line 600 can be accelerated.

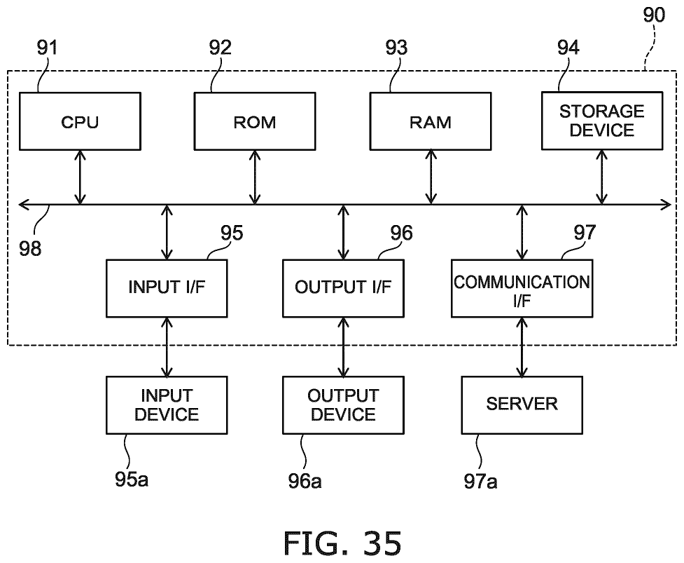

FIG. 35 is a schematic diagram showing a hardware configuration.

The generating device 10 and the execution device 40 each include, for example, the components of a computer 90 shown in FIG. 35. The computer 90 includes a CPU 91, a ROM 92, a RAM 93, a storage device 94, an input interface 95, an output interface 96, and a communication interface 97.

The ROM 92 stores a program for controlling operations of the computer 90. In the ROM 92, a program necessary for causing the computer 90 to implement the above-described processes is stored. The RAM 93 functions as a storage area to which the programs stored in the ROM 92 are loaded.

The CPU 91 includes a processing circuit. The CPU 91 uses the RAM 93 as a work memory to execute programs stored in at least either the ROM 92 or the storage device 94. While executing the programs, the CPU 91 controls each component via a system bus 98 to perform various processes.

The storage device 94 stores data necessary for execution of programs and data obtained as a result of execution of programs.

The input interface (I/F) 95 connects the computer 90 with an input device 95a. The input I/F 95 is, for example, a serial bus interface, such as USB. The CPU 91 can read various types of data from the input device 95a via the input I/F 95.

The output interface (I/F) 96 connects the computer 90 with an output device 96a. The output I/F 96 is a video output interface, such as Digital Visual Interface (DVI) or High-Definition Multimedia Interface (HDMI (registered trademark)). The CPU 91 can transmit data to the output device 96a via the output I/F 96 to make the output device 96a display an image.

The communication interface (I/F) 97 connects a server 97a outside the computer 90 with the computer 90. The communication I/F 97 is, for example, a network card, such as a LAN card. The CPU 91 can read various types of data from the server 97a via the communication I/F 97.

The storage device 94 includes one or more selected from among a hard disk drive (HDD) and a solid state drive (SSD). The input device 95a includes one or more selected from among a mouse, a keyboard, a microphone (voice input), and a touch pad. The output device 96a includes one or more selected from among a monitor and a projector. A device, such as a touch panel, having the functions of both the input device 95a and the output device 96a may be used.

The functions of each of the generating device 10 and the execution device 40 may be implemented as one computer or may be implemented by cooperation between a plurality of computers. Processing of various types of data described above may be recorded, as a program that can be executed by a computer, on a magnetic disk (examples of which include a flexible disk and a hard disk), an optical disk (examples of which include a CD-ROM, a CD-R, a CD-RW, a DVD-ROM, a DVD+R, and DVD+RW), a semiconductor memory, or another non-transitory computer-readable storage medium.

For example, information recorded on a recording medium can be read by a computer (or an embedded system). The recording medium can have any record format (storage format). For example, the computer reads a program from the recording medium and causes the CPU to execute instructions described in the program, on the basis of the program. The computer may obtain (or read) the program through a network.

The embodiment of the invention includes the following features.

### (Appendix 1)

A processing method causing a computer to:
refer to an individual model indicating a measure against a cause of a defect mode in a product; and
generate consolidated models for a plurality of the defect modes respectively, each consolidated model of the consolidated models being generated by rearranging and connecting a plurality of the individual models in accordance with a plurality of weights respectively set for a plurality of the causes.

### (Appendix 2)

The processing method according to appendix 1, further causing the computer to:
obtain quality data regarding the product; and
execute, when the quality data indicates an occurrence of any defect mode among the plurality of defect modes, a consolidated model among the consolidated models, the consolidated model corresponding to the occurring defect mode.

### (Appendix 3)

The processing method according to appendix 2, further causing the computer to: receive check data regarding a cause among the plurality of causes, the check data being obtained upon execution of the consolidated model.

### (Appendix 4)

The processing method according to appendix 3, further causing the computer to: update a weight of at least a cause among the plurality of causes by using the check data.

### (Appendix 5)

The processing method according to appendix 4, further causing the computer to: update one or more of the consolidated models in accordance with the updated weight.

### (Appendix 6)

The processing method according to any one of appendixes 1 to 5, further causing the computer to:
cause a display device to display a user interface showing data regarding any of the plurality of individual models; and accept an edit of the data on the user interface.

### (Appendix 7)

The processing method according to any one of appendixes 1 to 6, further causing the computer to: upon execution of the consolidated model, cause a display device to display one or more individual models of the plurality of individual models, the one or more individual models being rearranged.

### (Appendix 8)

The processing method according to any one of appendixes 2 to 5, in which each of the consolidated models is generated by using one or more individual models of the plurality of individual models, the one or more individual models corresponding to one or more causes of the plurality of causes, the one or more causes having weights greater than a threshold value.

### (Appendix 9)

The processing method according to any one of appendixes 2 to 5, in which upon execution of the consolidated model, only one or more individual models of the plurality of individual models are executed, the one or more individual models corresponding to one or more causes of the plurality of causes, the one or more causes having weights greater than a threshold value.

### (Appendix 10)

The processing method according to any one of appendixes 1 to 9, in which the plurality of weights are determined by using one or more selected from a first group consisting of a score based on a number of occurrences of each of the plurality of causes, a score based on a configuration of a production line of the product, a score based on a scale of staff related to production of the product, a score based on a repair man-hours for each of the plurality of defect modes, a score based on a price of a component of the product, a score based on a difficulty of production of the product, a score based on a type of a component included in the product, a score based on a production environment of the product, a score based on a number of years elapsed of manufacturing equipment for the product, and a score based on a time of an occurrence of each of the plurality of causes.

### (Appendix 11)

The processing method according to appendix 10, in which the plurality of weights are obtained by inputting the one or more selected from the first group into a neural network.

### (Appendix 12)

A program causing the computer according to any one of appendixes 1 to 11 to perform the processing method according to any one of appendixes 1 to 11.

### (Appendix 13)

A storage medium storing a program causing the computer according to any one of appendixes 1 to 12 to perform the processing method according to any one of appendixes 1 to 12.

According to the embodiment described above, a processing method, a generating device, a processing system, a program, and a storage medium capable of automatically generating consolidated models that are effective in remedying defects are provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Further, the above-described embodiments can be implemented in combination with each other.

1. A processing method causing a computer to:
refer to an individual model indicating a measure against a cause of a defect mode in a product; and
generate consolidated models for a plurality of the defect modes respectively, each consolidated model of the consolidated models being generated by rearranging and connecting a plurality of the individual models in accordance with a plurality of weights respectively set for a plurality of the causes.

2. The processing method according to claim 1, further causing the computer to:
obtain quality data regarding the product; and
execute, when the quality data indicates an occurrence of any defect mode among the plurality of defect modes, one of the consolidated models corresponding to the occurring defect mode.

3. The processing method according to claim 2, further causing the computer to receive check data regarding a part of the plurality of causes, the check data being obtained upon execution of the consolidated model.

4. The processing method according to claim 3, further causing the computer to: update a weight of at least a part of the plurality of causes by using the check data.

5. The processing method according to claim 4, further causing the computer to: update one or more of the consolidated models in accordance with the updated weight.

6. The processing method according to claim 1, further causing the computer to:
cause a display device to display a user interface showing data regarding any of the plurality of individual models; and
accept an edit of the data on the user interface.

7. The processing method according to claim 1, further causing the computer to: upon execution of the consolidated model, cause a display device to display one or more individual models of the plurality of individual models, the one or more individual models being rearranged.

8. The processing method according to claim 2, wherein each of the consolidated models is generated by using one or more individual models of the plurality of individual models, the one or more individual models corresponding to one or more causes of the plurality of causes, the one or more causes having weights greater than a threshold value.

9. The processing method according to claim 2, wherein upon execution of the consolidated model, only one or more individual models of the plurality of individual models are executed, the one or more individual models corresponding to one or more causes of the plurality of causes, the one or more causes having weights greater than a threshold value.

10. The processing method according to claim 1, wherein the plurality of weights are determined by using one or more selected from a first group consisting of a score based on a number of occurrences of each of the plurality of causes, a score based on a configuration of a production line of the product, a score based on a scale of staff related to production of the product, a score based on a repair man-hours for each of the plurality of defect modes, a score based on a price of a component of the product, a score based on a difficulty of production of the product, a score based on a type of a component included in the product, a score based on a production environment of the product, a score based on a number of years elapsed of manufacturing equipment for the product, and a score based on a time of an occurrence of each of the plurality of causes.

11. The processing method according to claim 10, wherein the plurality of weights are obtained by inputting the one or more selected from the first group into a neural network.

12. A generating device configured to:
refer to an individual model indicating a measure against a cause of a defect mode in a product; and
generate consolidated models for a plurality of the defect modes respectively, each consolidated model of the consolidated models being generated by rearranging and connecting a plurality of the individual models in accordance with a plurality of weights respectively set for a plurality of the causes.

13. A processing system comprising:
the generating device according to claim 12; and
a collection system configured to collect quality data regarding the product.

14. A program causing the computer to perform the processing method according to claim 1.

15. A non-transitory computer-readable storage medium storing a program causing the computer to perform the processing method according to claim 1.
